(19) United States
(12) Patent Application Publication
(10) Pub. No.: US 2026/0122958 A1
(43) Pub. Date: Apr. 30, 2026

(54) SEMICONDUCTOR DEVICE, ELECTRONIC APPARATUS HAVING THE SEMICONDUCTOR DEVICE, AND METHOD OF MANUFACTURING THE SEMICONDUCTOR DEVICE

(71) Applicant: Samsung Electronics Co., Ltd., Suwon-si (KR)

(72) Inventors: Kyooho JUNG, Suwon-si (KR); Jungkyun KIM, Suwon-si (KR); Sangwook KIM, Suwon-si (KR); Jeeeun YANG, Suwon-si (KR)

(73) Assignee: Samsung Electronics Co., Ltd., Suwon-si (KR)

(21) Appl. No.: 19/194,428

(22) Filed: Apr. 30, 2025

(30) Foreign Application Priority Data
Oct. 29, 2024 (KR) 10-2024-0149927

(51) Int. Cl. H10D 30/63; H10B 12/00; H10D 30/01; H10D 30/60; H10D 62/17; H10D 62/80; H10D 64/27; H10D 64/62

(52) U.S. Cl. CPC H10D 30/63; H10B 12/05; H10B 12/482; H10D 30/023; H10D 30/025; H10D 30/611; H10D 62/292; H10D 62/875; H10D 64/512; H10D 64/514; H10D 64/518; H10D 64/62

(57) ABSTRACT

Provided are a semiconductor device, an electronic apparatus including the semiconductor device, and/or a method of manufacturing the semiconductor device. The semiconductor device includes a substrate, an oxide semiconductor layer on the substrate, a first electrode on the oxide semiconductor layer, a second electrode on the oxide semiconductor layer and apart from the first electrode, and a first layer, a second layer, and a third layer in at least one of a region between the oxide semiconductor layer and the first electrode and a region between the oxide semiconductor layer and the second electrode. The second layer includes at least one selected from tantalum oxide, niobium oxide, strontium oxide, and aluminum oxide.

### CROSS-REFERENCE TO RELATED APPLICATION

This application is based on and claims priority under 35 U.S.C. § 119 to Korean Patent Application No. 10-2024-0149927, filed on Oct. 29, 2024, in the Korean Intellectual Property Office, the disclosure of which is incorporated by reference herein in its entirety.

### BACKGROUND

Some example embodiments relate to a semiconductor device including a layer capable of reducing contact resistance between an electrode and an oxide semiconductor layer, an electronic apparatus including the semiconductor device, and/or a method of manufacturing the semiconductor device.

Transistors, which are semiconductor devices serving as electrical switches, are employed in various integrated circuit devices such as memory devices, driver integrated circuits (ICs), and logic devices. Spaces for transistors have been rapidly reduced in IC devices to increase the integration density of IC devices. Thus, research has been conducted to decrease the size of transistors while maintaining the performance of transistors.

Gate electrodes are key elements of transistors. When voltage is applied to a gate electrode, a channel adjacent to the gate electrode opens a path for a current to flow, and when no voltage is applied to the gate electrode, the channel blocks flow of current. The performance of semiconductors depends on the efficiency of reducing and managing leakage current at gate electrodes and channels. The larger the contact area between a gate electrode and a channel, the higher the power efficiency.

As semiconductor processes become more miniaturized, the size of transistors decreases, and the contact area between gate electrodes and channels decreases, causing issues, for example related to short channel effects. For example, issues, such as one or more of threshold voltage variation, carrier velocity saturation, deterioration of subthreshold characteristics, and reduction of on-current, may occur.

Therefore, solutions are being sought to overcome or improve over short channel effects and effectively reduce a channel length.

### SUMMARY

Provided is a semiconductor device including a layer capable of reducing contact resistance between an electrode and an oxide semiconductor layer.

Alternatively or additionally, provided is an electronic apparatus including a semiconductor device with a layer capable of reducing contact resistance between an electrode and an oxide semiconductor layer.

Alternatively or additionally, provided is a method of manufacturing a semiconductor device including a layer capable of reducing contact resistance between an electrode and an oxide semiconductor layer.

Additional aspects will be set forth in part in the description which follows and, in part, will be apparent from the description, and/or may be learned by practice of one or more example embodiments.

According to some example embodiments, a semiconductor device includes a substrate, an oxide semiconductor layer on the substrate, a first electrode on the oxide semiconductor layer, a second electrode on the oxide semiconductor layer and apart from the first electrode, a first layer, a second layer, and a third layer in at least one of a region between the oxide semiconductor layer and the first electrode and a region between the oxide semiconductor layer and the second electrode, a gate insulating layer on the oxide semiconductor layer, and a gate electrode on the gate insulating layer. The first layer includes an indium-containing metal oxide layer including at least one of metals included in the first electrode or the second electrode. The second layer includes at least one selected from tantalum oxide, niobium oxide, strontium oxide, and aluminum oxide. The third layer includes at least one of indium oxide or indium tin oxide.

The first electrode and the second electrode may include at least one selected from W, TiN, Mo, MoN, Ru, and TiSiN.

The first layer may include at least one selected from indium-containing TiO₂, indium-containing WOₓ, indium-containing MoOₓ, and indium-containing RuO.

The second layer may have a thickness of greater than about 0 nm to less than about 2 nm.

The first electrode and the second electrode may be arranged apart from each other in a direction perpendicular to the substrate.

The oxide semiconductor layer may include an oxide including at least one selected from indium (In), gallium (Ga), zinc (Zn), tungsten (W), tin (Sn), and hafnium (Hf).

The gate electrode may surround the oxide semiconductor layer.

Length directions of the oxide semiconductor layer, the gate insulating layer, and the gate electrode may be perpendicular to the substrate, and the oxide semiconductor layer, the gate insulating layer, and the gate electrode may be arranged in a direction parallel to the substrate.

The oxide semiconductor layer may have a U-shaped cross-section.

The oxide semiconductor layer may include a first oxide semiconductor layer having an L shape with a length in a direction perpendicular to the substrate, and a second oxide semiconductor layer symmetrical to the first oxide semiconductor layer with respect to the direction perpendicular to the substrate. The gate electrode may include a first gate electrode having a length in the direction perpendicular to the substrate, and a second gate electrode symmetrical to the first gate electrode with respect to the direction perpendicular to the substrate.

The first electrode, the first layer, the second layer, the third layer, and the oxide semiconductor layer may have an identical width.

Alternatively or additionally according to some example embodiments, an electronic apparatus includes a semiconductor device and a capacitor electrically connected to the semiconductor device.

The semiconductor device includes a substrate, an oxide semiconductor layer on the substrate, a first electrode on the oxide semiconductor layer, a second electrode on the oxide semiconductor layer and apart from the first electrode, a first layer, a second layer, and a third layer in at least one of a region between the oxide semiconductor layer and the first electrode and a region between the oxide semiconductor layer and the second electrode, a gate insulating layer on the oxide semiconductor layer, and a gate electrode provided on the gate insulating layer. The first layer is an indium-containing metal oxide layer including at least one of metals included in the first electrode or the second electrode. The second layer includes at least one selected from tantalum oxide, niobium oxide, strontium oxide, and aluminum oxide. The third layer includes at least one of indium oxide or indium tin oxide.

The first electrode may comprise a plurality of bit lines extending in a first direction. The oxide semiconductor layer may include a plurality of oxide semiconductor layers respectively and electrically connected to the plurality of bit lines and extending in a second direction orthogonal to the first direction. The gate electrode may comprise a plurality of word lines extending across the plurality of oxide semiconductor layers in a third direction orthogonal to the first and second directions.

Alternatively or additionally according to some example embodiments, a method of manufacturing a semiconductor device includes forming a first electrode on a substrate, forming a first layer by oxidizing an interface of the first electrode, forming a second layer on the first layer, forming a third layer on the second layer, doping the first layer with indium by a heat treatment diffusing indium from the third layer into the first layer, and forming an oxide semiconductor layer on the third layer. The first layer is an indium-containing metal oxide layer including at least one of metals included in the first electrode. The second layer includes at least one selected from tantalum oxide, niobium oxide, strontium oxide, and aluminum oxide. The third layer includes at least one of indium oxide or indium tin oxide.

### BRIEF DESCRIPTION OF THE DRAWINGS

The above and other aspects, features, and advantages of some example embodiments will be more apparent from the following description taken in conjunction with the accompanying drawings, in which:

FIG. 1 is a view illustrating a semiconductor device according to some example embodiments;

FIG. 2 is a view illustrating a semiconductor device according to some example embodiments;

FIG. 3 is a view illustrating a semiconductor device according to some example embodiments;

FIG. 4 is a view illustrating a modification of an oxide semiconductor layer in the semiconductor device depicted in FIG. 3;

FIG. 5 is a view illustrating modifications of first, second, and third layers in the semiconductor device depicted in FIG. 3;

FIG. 6 is a view illustrating a semiconductor device according to some example embodiments;

FIG. 7 is a view illustrating a semiconductor device according to comparative example;

FIG. 8 is a current-voltage (I-V) graph for comparison between a semiconductor device of some example embodiments and a semiconductor device of a comparative example;

FIG. 9 is an I-V graph for comparing an embodiment, in which the thickness of a second layer of a semiconductor device is changed, with a comparative example;

FIG. 10 is a flowchart illustrating a method of manufacturing a semiconductor device, according to some example embodiments;

FIGS. 11 to 22 are views illustrating a method of manufacturing a semiconductor device, according to some example embodiments;

FIG. 23 is a view illustrating an example in which a semiconductor device is applied to dynamic random access memory (DRAM) according to some example embodiments;

FIG. 24 is a view illustrating an example in which a semiconductor device is applied to a vertically stacked memory device according to some example embodiments;

FIG. 25 is a view illustrating an example in which a semiconductor device is applied to another vertically stacked memory device according to some example embodiments;

FIG. 26 is a block diagram schematically illustrating a display driver integrated circuit (display driver IC or DDI) including a semiconductor device, and a display apparatus including the DDI, according to some example embodiments;

FIG. 27 is a circuit diagram illustrating a complementary metal oxide semiconductor (CMOS) inverter including a semiconductor device according to some example embodiments;

FIG. 28 is a circuit diagram illustrating a CMOS static random access memory (SRAM) device including a semiconductor device according to some example embodiments;

FIG. 29 is a circuit diagram illustrating a CMOS NAND circuit including a semiconductor device according to some example embodiments;

FIG. 30 is a block diagram illustrating an electronic system illustrating a semiconductor device according to some example embodiments; and

FIG. 31 is a block diagram illustrating an electronic system including a semiconductor device according to some example embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, semiconductor devices, electronic apparatuses including the semiconductor devices, and method of manufacturing the semiconductor devices will be described according to various embodiments with reference to the accompanying drawings. In the drawings, like reference numbers refer to like elements, and the size of each element may be exaggerated for clarity of illustration. It will be understood that although terms such as “first” and “second” may be used herein to describe various elements, these elements should not be limited by these terms. These terms are only used to distinguish one element from another.

As used herein, singular forms may include plural forms as well unless the context clearly indicates otherwise. It will be further understood that the terms “comprises,” “comprising,” “includes,” and/or “including” used herein specify the presence of stated features or elements, but do not preclude the presence or addition of one or more other features or elements. In the drawings, the size or thickness of each element may be exaggerated for clarity of illustration. Furthermore, it will be understood that when a material layer is referred to as being “on” or “above” a substrate or another layer, it may be directly on the substrate or the other layer, or intervening layers may also be present. Furthermore, in the following embodiments, a material included in each layer is an example, and another material may be used in addition to or instead of the material.

In the disclosure, terms such as “unit” or “module” may be used to denote a unit that has at least one function or operation and is implemented with hardware, software, or a combination of hardware and software.

Specific executions described herein are merely examples and do not limit the scope of the disclosure in any way. For simplicity of description, other functional aspects of conventional electronic configurations, control systems, software and the systems may be omitted. Furthermore, line connections or connection members between elements depicted in the drawings represent functional connections and/or physical or circuit connections by way of example, and in actual applications, they may be replaced or embodied as various additional functional connections, physical connections or circuit connections.

An element referred to with the definite article or a demonstrative pronoun may be construed as the element or the elements even though it has a singular form.

Operations of a method may be performed in appropriate order unless explicitly described in terms of order or described to the contrary. In addition, examples or certain terms (for example, “such as” and “etc.”) are used for the purpose of description and are not intended to limit the scope of example embodiments unless defined by the claims.

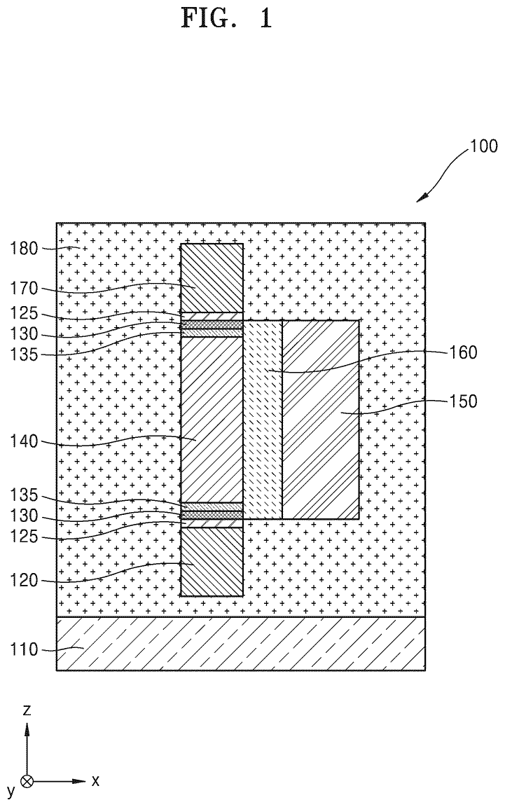

FIG. 1 is a view illustrating a semiconductor device 100 according to some example embodiments.

Referring to FIG. 1, the semiconductor device 100 includes a substrate 110, an oxide semiconductor layer 140 provided on the substrate 110, a first electrode 120 provided on the oxide semiconductor layer 140, and a second electrode 170 provided on the oxide semiconductor layer 140 at a position apart from the first electrode 120. A first layer 125, a second layer 130, and a third layer 135 may be provided in at least one of a region between the oxide semiconductor layer 140 and the first electrode 120 and a region between the oxide semiconductor layer 140 and the second electrode 170. FIG. 1 illustrates an example in which a first layer 125, a second layer 130, and a third layer 135 are provided in the region between the oxide semiconductor layer 140 and the first electrode 120, and a first layer 125, a second layer 130, and a third layer 135 are provided in the region between the oxide semiconductor layer 140 and the second electrode 170.

The substrate 110 may be or may include an insulating substrate and/or a semiconductor substrate with an insulating layer formed on a surface thereof. Alternatively or additionally, the substrate 110 may be or may include a semiconductor substrate. The semiconductor substrate may include, for example, one or more of Si, Ge, SiGe, a Group III-V semiconductor material, or the like. The substrate 110 may be or may include, for example, a silicon substrate with a silicon oxide layer formed on a surface thereof, but is not limited thereto.

The first electrode 120 may include a metallic material. The first electrode 120 may include at least one selected from among tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), antimony (Sb), vanadium (V), ruthenium (Ru), platinum (Pt), zinc (Zn), and magnesium (Mg). Alternatively, the first electrode 120 may include a nitride containing at least one of the listed elements. For example, the first electrode 120 may include at least one selected from W, TiN, Mo, MoN, Ru, and TiSiN. The first electrode 120 may be apart from the substrate 110; for example, a mold insulating layer 180 may be between the first electrode 120 and the substrate 110. In some example embodiments, the first electrode 120 may include Zn in an amount of 10 at % or less. In the first electrode 120, the Zn content may be 10 at % or less relative to the total content of metal elements. Here, the Zn content may refer to the content of Zn in the first electrode 120 relative to the total content of metal elements in the first electrode 120, excluding oxygen. Alternatively or additionally, the first electrode 120 may include Zn in an amount of 5 at % or less.

The first layers 125 may each be or include an indium-containing oxide layer including at least one of metals included in the first electrode 120 or the second electrode 170. The first layers 125 may each be or include an oxide layer formed from the first electrode 120 or the second electrode 170 and doped with an indium. For example, the first layers 125 may each be or include an indium-doped oxide layer including at least one selected from tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), antimony (Sb), vanadium (V), ruthenium (Ru), platinum (Pt), zinc (Zn), magnesium (Mg), and any combination thereof. For example, the first layers 125 may each include at least one selected from indium-containing TiO₂, indium-containing WOₓ, indium-containing MoOₓ, and indium-containing RuO. The second layers 130 may each include at least one selected from tantalum oxide, niobium oxide, strontium oxide, and aluminum oxide. For example, the second layers 130 may each include TaOₓ, NbOₓ, SrOₓ, or Al₂O₃. The second layers 130 may each have a thickness of greater than about 0 nm to less than about 2 nm. The second layers 130 may reduce contact resistance of the first electrode 120 and/or the second electrode 170 by lowering an energy barrier height between the first electrode 120 and the oxide semiconductor layer 140 and an energy barrier height between the second electrode 170 and the oxide semiconductor layer 140. The third layers 135 may each include indium oxide and/or indium tin oxide (ITO). The third layers 135 may serve as layers that supply indium to the first layers 125. The first layer 125 provided between the first electrode 120 and the oxide semiconductor layer 140 may be in contact with the first electrode 120. The first layer 125 provided between the second electrode 170 and the oxide semiconductor layer 140 may be in contact with the second electrode 170. The second layers 130 may be disposed between the first layers 125 and the third layers 135. However, the positions of the second layers 130 and the third layers 135 may be switched. For example, the third layers 135 may be disposed between the first layers 125 and the second layers 130. Each set of the first layers 125, the second layers 130, and the third layers 135 may be stacked without other layers therebetween. The third layers 135 may be in contact with, e.g., in direct contact with the oxide semiconductor layer 140. However, the third layers 135 are not limited thereto. For example, other layers may be disposed between the oxide semiconductor layer 140 and the third layers 135.

In some example embodiments, materials and/or thicknesses of the first layer 125 between the first electrode 120 and the oxide channel layer 140 may be the same, or different, than materials and/or thicknesses of the first layer 124 between the oxide channel layer 140 and the second electrode 170. Alternatively or additionally, materials and/or thicknesses of the second layer 130 between the first electrode 120 and the oxide semiconductor layer 140 may be the same, or different, from the materials and/or thicknesses of the second layer 130 between the oxide semiconductor layer 140 and the second electrode 170. Alternatively or additionally, materials and/or thicknesses of the third layer 135 between the first electrode 120 and the oxide semiconductor layer 140 may be the same, or different, from the materials and/or thicknesses of the third layer 135 between the oxide semiconductor layer 140 and the second electrode 170. In particular, thicknesses and/or material compositions of the first to third layers 125, 130, and 135 may be independent of each other. Example embodiments are not limited thereto.

The oxide semiconductor layer 140 may include an oxide containing at least one selected from indium (In), gallium (Ga), zinc (Zn), tungsten (W), tin (Sn), and hafnium (Hf). For example, the oxide semiconductor layer 140 may include zinc indium oxide (ZIO), indium gallium oxide (IGO), or indium gallium zinc oxide (IGZO). The oxide semiconductor layer 140 may include a material selected from among InGaZnO, ZrInZnO, InGaZnO₄, ZnInO, In₂O₃, HfInZnO, and a combination thereof.

Alternatively or additionally, the oxide semiconductor layer 140 may include indium (In) and zinc (Zn). In this case, the content of indium (In) in the oxide semiconductor layer 140 may be equal to or greater than the content of zinc (Zn) in the oxide semiconductor layer 140. For example, the oxide semiconductor layer 140 may include (In)_{b1}(Zn)_{b2} (M)_{b3}O Here, M may refer to Sn, Ga, Hf, or a combination thereof; b1 may refer to a real number satisfying 0<b1≤10; b2 may refer to a real number satisfying 0<b2≤10; b3 may refer to a real number satisfying 0<b3≤10; and b1>b2.

The first electrode 120 and the second electrode 170 may be apart from each other in a direction (Z direction) perpendicular to the substrate 110, and the oxide semiconductor layer 140 may be longitudinally disposed between the first electrode 120 and the second electrode 170. Thus, the first electrode 120, the first layers 125, the second layers 130, the third layers 135, the oxide semiconductor layer 140, and the second electrode 170 may be arranged in a line in the direction (Z direction) perpendicular to the substrate 110. The first electrode 120, the first layers 125, the second layers 130, the third layers 135, the oxide semiconductor layer 140, and the second electrode 170 may have the same width, e.g., the same width in the X direction; example embodiments are not limited thereto.

A length direction of the oxide semiconductor layer 140 may be parallel to the direction (Z direction) perpendicular to the substrate 110. The oxide semiconductor layer 140 may be used as a channel layer. The semiconductor device 100 may have a vertical channel transistor (VCT) structure including a vertical channel region in which the oxide semiconductor layer 140 extends in a vertical direction (Z direction) from the first electrode 120.

As used herein, the term “length direction” refers to a direction in which the length of an element is defined as shown in the drawings.

A gate electrode 150 may be provided on at least one side of the oxide semiconductor layer 140. A gate insulating layer 160 may be disposed between the oxide semiconductor layer 140 and the gate electrode 150. The gate electrode 150 may be disposed such that the length direction of the gate electrode 150 may be parallel to the direction (Z direction) perpendicular to the substrate 110. The oxide semiconductor layer 140, the gate insulating layer 160, and the gate electrode 150 may be arranged in a line in a direction (X direction) parallel to the substrate 110.

In some example embodiments, as illustrated in FIG. 1, the gate insulating layer 160 may extend from, e.g., may be flush with an interface between the first layer 125 and the second layer 130 that are between the first electrode 120 and the semiconductor oxide layer 140; alternatively or additionally, the gate insulating layer 160 may extend from, e.g., be flush with, an interface between the second layer 130 and the first layer 125 that are between the semiconductor oxide layer 140 and the second electrode 170. Example embodiments are not limited thereto.

A mold insulating layer 180 may be provided on the substrate 110 and may fill an empty space. In some example embodiments, the first electrode 120 may be disposed apart from the substrate 110 by the mold insulating layer 180.

As described above, the semiconductor device 100 of some example embodiments may include the first layer 125, the second layer 130, and the third layer 135 between the first electrode 120 and the oxide semiconductor layer 140, which may reduce the contact resistance of the first electrode 120. Alternatively or additionally, the semiconductor device 100 of some example embodiments may include the first layer 125, the second layer 130, and the third layer 135 between the second electrode 170 and the oxide semiconductor layer 140, which may reduce the contact resistance of the second electrode 170.

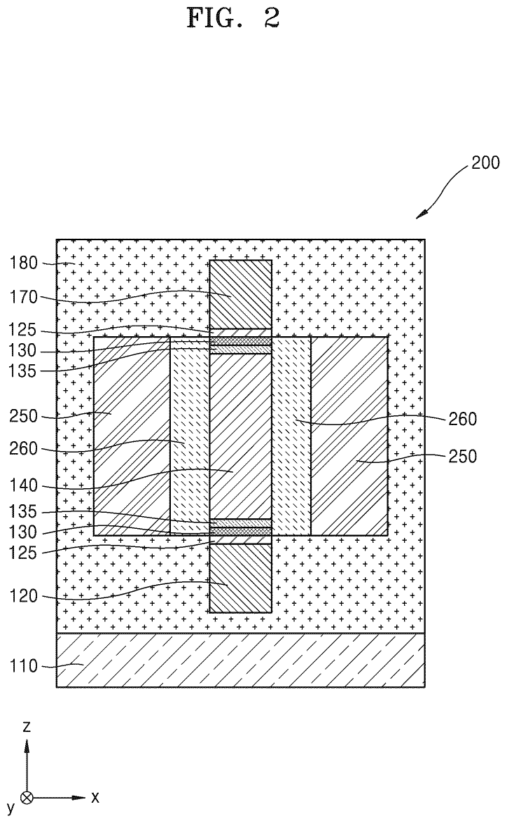

FIG. 2 is a view illustrating a semiconductor device 200 according to some example embodiments. In FIGS. 2 and 1, elements denoted with the reference numerals have substantially the same structures and operational effects, and therefore, repeated descriptions thereof are omitted here.

The semiconductor device 200 includes a first electrode 120, first layers 125, second layers 130, third layers 135, an oxide semiconductor layer 140, and a second electrode 170 that are arranged in a direction (Z direction) perpendicular to a substrate 110. Gate insulating layers 260 may be provided around the oxide semiconductor layer 140, and gate electrodes 250 may be provided around the gate insulating layers 260. Because the gate electrodes 250 are provided around the oxide semiconductor layer 140, a contact area between the oxide semiconductor layer 140 and the gate electrodes 250 increase, thereby mitigating short channel effects.

A thickness and/or a material composition of gate insulation layers 260 on both sides of the oxide semiconductor layer 140 may be the same, or different. A thickness and/or a material composition of the gate electrodes 250 on both sides of the semiconductor oxide layer 140 may be the same, or different.

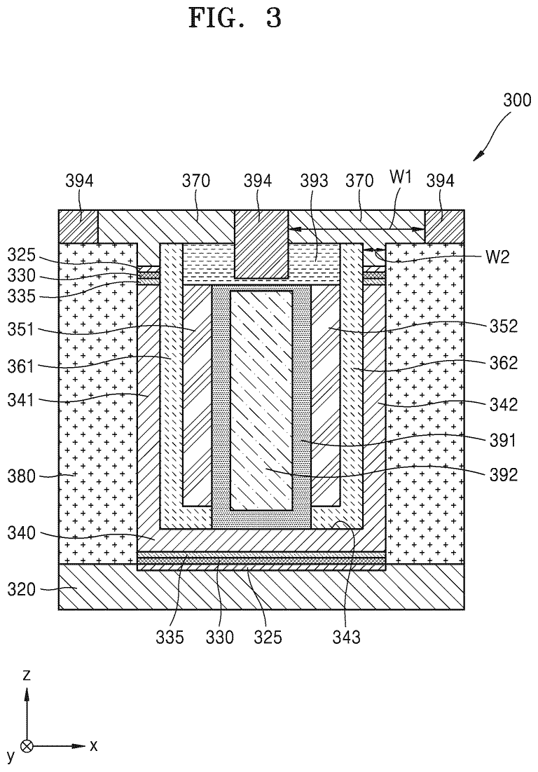

FIG. 3 is a view illustrating a semiconductor device 300 according to some example embodiments.

The semiconductor device 300 may include a first electrode 320, a first layer 325 provided on the first electrode 320, a second layer 330 provided on the first layer 325, a third layer 335 provided on the second layer 330, and an oxide semiconductor layer 340 provided on the third layer 335. The first layer 325, the second layer 330, and the third layer 335 have substantially the same structures and operational effects as the first layers 125, the second layers 130, and the third layers 135 described with reference to FIG. 1, and thus, repeated descriptions thereof are omitted here.

The oxide semiconductor layer 340 may have a U-shaped cross-section. The oxide semiconductor layer 340 may include a bottom portion 343 in contact with the third layer 335, a first vertical extension portion 341 extending from an end of the bottom portion 343 in a direction (Z direction) perpendicular to the first electrode 320, and a second vertical extension portion 342 extending from the other end of the bottom portion 343 in the direction (Z direction) perpendicular to the first electrode 320.

A first gate electrode 351 may be disposed apart from the first vertical extension portion 341, and a second gate electrode 352 may be disposed apart from the second vertical extension portion 342. A first gate insulating layer 361 may be provided between the first vertical extension portion 341 and the first gate electrode 351, and a second gate insulating layer 362 may be provided between the second vertical extension portion 342 and the second gate electrode 352.

At least one of the first gate electrode 351 and the second gate electrode 352 may extend in a second horizontal direction (y direction). The first gate electrode 351 and the second gate electrode 352 may be apart from each other. At least one of the first gate electrode 351 and the second gate electrode 352 may form or may correspond to a word line WL. An electrical signal input to the first gate electrode 351 may differ from an electrical signal input to the second gate electrode 352. The first gate electrode 351 may control a channel of the first vertical extension portion 341, and the second gate electrode 352 may control a channel of the second vertical extension portion 342.

An insulating liner 391 may be disposed between the first gate electrode 351 and second gate electrode 352 that are arranged apart from each other. The insulating liner 391 may be conformally disposed on opposing side walls of the first gate electrode 351 and the second gate electrode 352 and/or an upper surface of the oxide semiconductor layer 340. The insulating liner 391 may have an upper surface disposed on the same plane as the first gate electrode 351 and the second gate electrode 352. The insulating liner 391 may include, for example, silicon nitride; however, example embodiments are not limited thereto. A filling insulating layer 392 may be provided on the insulating liner 391 to fill a space between the first gate electrode 351 and the second gate electrode 352. The filling insulating layer 392 may include, for example, silicon oxide. An upper insulating layer 393 may be disposed on upper surfaces of the first gate electrode 351, the second gate electrode 352, and/or the filling insulating layer 392. An upper surface of the upper insulating layer 393 may be at the same level as an upper surface of mold insulating layers 380.

A second electrode 370 may be disposed above the oxide semiconductor layer 340. A first layer 325, a second layer 330, and a third layer 335 may be provided between the oxide semiconductor layer 340 and the second electrode 370. The second electrode 370 may serve as a landing pad. The second electrode 370 may include a left second electrode and a right second electrode. The first layer 325, the second layer 330, and the third layer 335 may be provided between the left second electrode and the oxide semiconductor layer 340, and between the right second electrode and the oxide semiconductor layer 340. The left second electrode may be electrically connected to the first vertical extension portion 341. The right second electrode may be electrically connected to the second vertical extension portion 342. The left second electrode and the right second electrode may not be electrically connected to each other. The second electrode 370 may include upper portions and lower portions. The upper portions of the second electrode 370 may be positioned at a level higher than upper surfaces of the mold insulating layers 380. The lower portions of the second electrode 370 may be positioned within second electrode recesses defined between the upper insulating layer 393 and the mold insulating layers 380. According to some example embodiments, in a first horizontal direction (X direction), the upper portions of the second electrode 370 may have a first width w1, and the lower portions of the second electrode 370 may have a second width w2 less than the first width w1. The lower portions of the second electrode 370 may be positioned within the second electrode recesses, and the upper portions of the second electrode 370 may have bottom surfaces that are provided, at lower sides of the second electrode 370, on the upper surfaces of the mold insulating layers 380 and the upper surface of the upper insulating layer 393. Thus, the second electrode 370 may have a T-shaped vertical cross-section. The bottom surfaces of the lower portions of the second electrode 370 may be in contact with an upper surface of the first vertical extension portion 341 and/or an upper surface of the second vertical extension portion 342. Side walls of the lower portions of the second electrode 370 may be aligned with the side walls of the first vertical extension portion 341 and side walls of the second vertical extension portion 342. The bottom surfaces of the lower portions of the second electrode 370 may be positioned at a higher level than the upper surface of the first gate electrode 351 and/or the upper surface of the second gate electrode 352, and portions of the side walls of the lower portions of the second electrode 370 may be covered by the first gate insulating layer 361 and/or the second gate insulating layer 362. Second electrode insulating layers 394 may be provided on the upper surfaces of the mold insulating layers 380 and the upper surface of the upper insulating layer 393 to surround the second electrode 370. The semiconductor device 300 may have a VCT structure in which the oxide semiconductor layer 340 extends in a vertical direction (Z direction) from the first electrode 320.

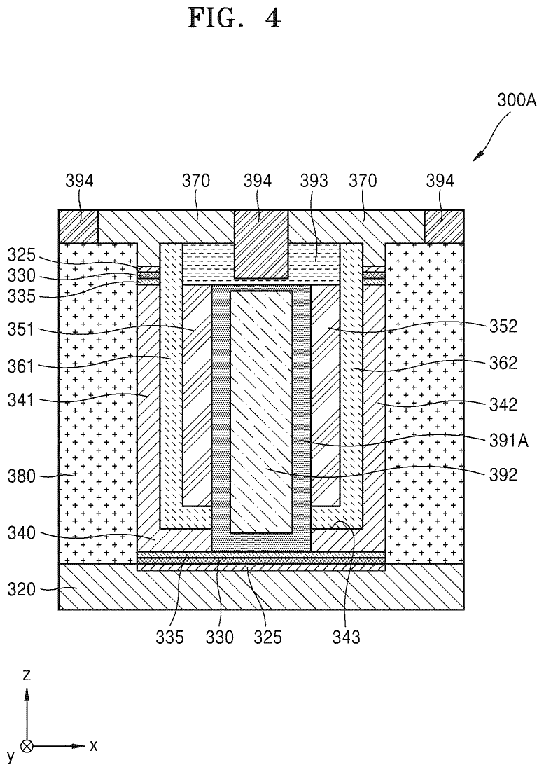

FIG. 4 illustrates a semiconductor device 300A according to some example embodiments.

In FIGS. 4 and 3, elements denoted with the reference numerals have substantially the same structures and operational effects, and therefore, repeated descriptions thereof are omitted here.

The shape of an oxide semiconductor layer shown in FIG. 4 may be different from the shape of the oxide semiconductor layer 340 shown in FIG. 3. The oxide semiconductor layer of the semiconductor device 300A may include a first oxide semiconductor layer 341 and a second oxide semiconductor layer 342. The first oxide semiconductor layer 341 may have an L-shaped cross-section, and the second oxide semiconductor layer 342 may have a shape that is symmetrical to the shape of the first oxide semiconductor layer 341 with respect to a Z direction. The first oxide semiconductor layer 341 and the second oxide semiconductor layer 342 are apart from each other. An insulating liner 391A may extend between the first oxide semiconductor layer 341 and the second oxide semiconductor layer 342.

The length direction of each of the first oxide semiconductor layer 341 and the second oxide semiconductor layer 342 may be parallel to a direction (Z direction) perpendicular to a substrate (not shown).

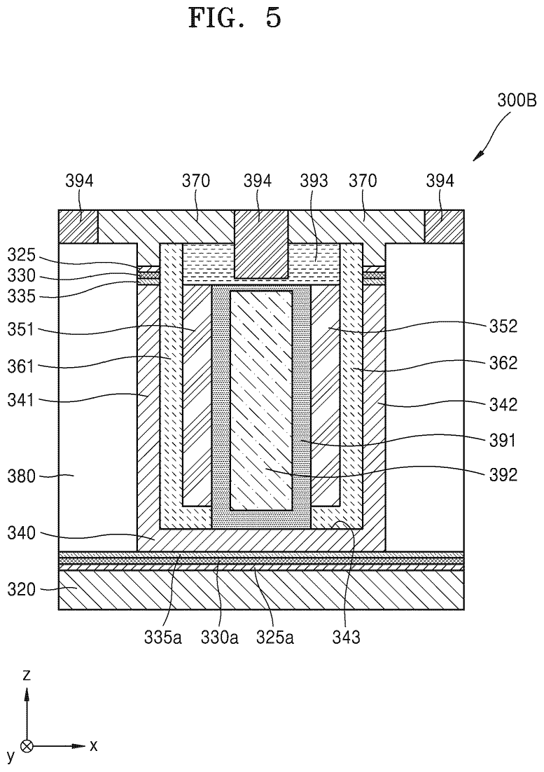

FIG. 5 illustrates modifications of first, second, and third layers of the semiconductor device 300A depicted in FIG. 3.

Comparing FIG. 5 with FIG. 4, a first layer 325a, a second layer 330a, and a third layer 335a may be provided on an entire region of a first electrode 320. Here, the first electrode 320 may function as a bit line, and the first layer 325a, the second layer 330a, and the third layer 335a may be provided along the first electrode 320.

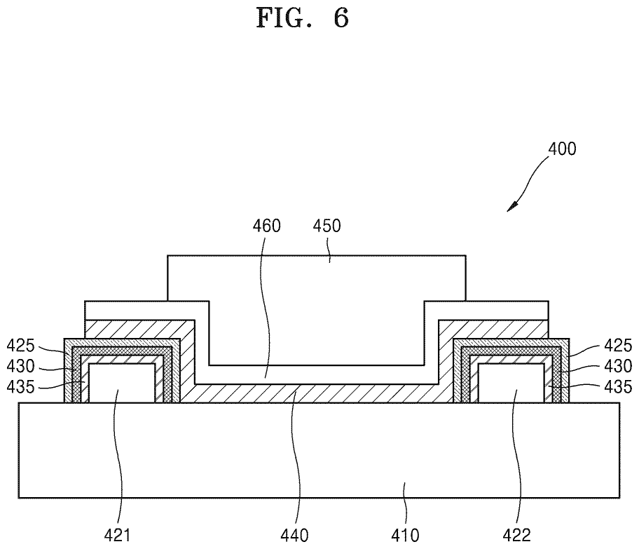

FIG. 6 illustrates a semiconductor device 400 according to some example embodiments.

The semiconductor device 400 may include a substrate 410, a first electrode 421 and a second electrode 422 arranged apart from each other on the substrate 410, an oxide semiconductor layer 440 provided on the substrate 410, a gate electrode 450 provided apart from the oxide semiconductor layer 440, and a gate insulating layer 460 provided between the oxide semiconductor layer 440 and the gate electrode 450. The oxide semiconductor layer 440 may extend to upper portions of the first electrode 421 and the second electrode 422.

A first layer 425, a second layer 430, and a third layer 435 may be provided in at least one of a region between the first electrode 421 and the oxide semiconductor layer 440 and a region between the second electrode 422 and the oxide semiconductor layer 440. FIG. 6 shows an example in which a first layer 425, a second layer 430, and a third layer 435 are provided between the first electrode 421 and the oxide semiconductor layer 440, and a first layer 425, a second layer 430, and a third layer 435 are provided between the second electrode 422 and the oxide semiconductor layer 440. Each of the first layer 425, the second layer 430, and the third layer 435 may surround upper and lateral surfaces of the first electrode 421. Similarly, each of the first layer 425, the second layer 430, and the third layer 435 may surround upper and lateral surfaces of the second electrode 422. However, embodiments are not limited thereto. For example, the first layer 425, the second layer 430, and the third layer 435 may be provided only in a region in which the first electrode 421 and the oxide semiconductor layer 440 face each other, and the first layer 425, the second layer 430, and the third layer 435 may be provided only in a region in which the second clad layer 442 and the oxide semiconductor layer 440 face each other. The semiconductor device 400 may be applied to a transistor with a planar channel structure.

The first layers 425, the second layers 430, the third layers 435, and the oxide semiconductor layer 440 may have substantially the same structures and operational effects as the first layers 125, the second layers 130, the third layers 135, and the oxide semiconductor layers 140 described in FIG. 1, and thus, repeated descriptions thereof are omitted here.

The gate electrode 450 may be apart from the oxide semiconductor layer 440. The gate insulating layer 460 may be provided between the oxide semiconductor layer 440 and the gate electrode 450. The gate electrode 450 may include at least one selected from a metal, a metal nitride, and a transparent conductive oxide (TCO). The gate insulating layer 460 may include an oxide containing at least one selected from hafnium (Hf), zirconium (Zr), aluminum (Al), or silicon (Si). When the semiconductor device 400 is an element of a memory cell, the gate electrode 450 may form a portion of a word line.

The first electrode 421 and the second electrode 422 may be disposed below a lower surface of the oxide semiconductor layer 440, and the gate electrode 450 may be disposed above an upper surface of the oxide semiconductor layer 440. However, embodiments are not limited thereto. For example, the first electrode 421, the second electrode 422, and the gate electrode 450 may be arranged on the same surface of the oxide semiconductor layer 440. The first electrode 421 may serve as a source electrode, and the second electrode 422 may serve as a drain electrode. The first electrode 421 and the second electrode 422 may include the same materials as the first electrode 120 and the second electrode 170 described in FIG. 1.

Next, operational effects of a semiconductor device are described according to some example embodiments.

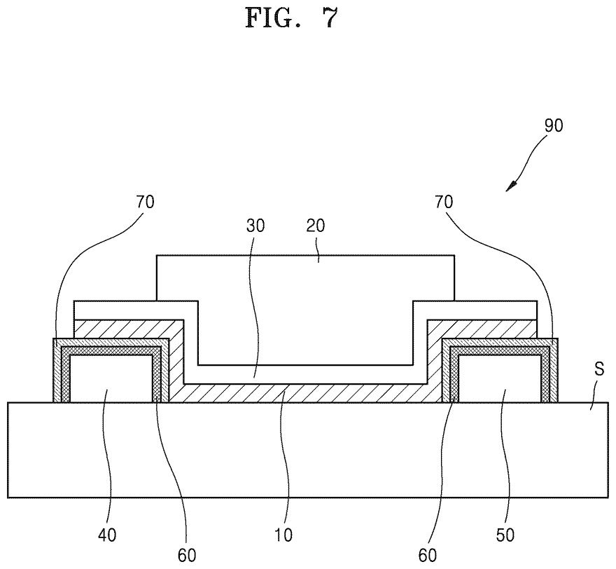

FIG. 7 illustrates a semiconductor device 90 according to a comparative example.

The semiconductor device 90 includes a substrate S, an oxide semiconductor layer 10, a gate electrode 20 disposed apart from the oxide semiconductor layer 10, a gate insulating layer 30 disposed between the oxide semiconductor layer 10 and the gate electrode 20, and first and second electrodes 40 and 50 arranged apart from each other below the oxide semiconductor layer 10. The first and second electrodes 40 and 50 may be or may include tungsten (W) electrodes, and may or may not include the same material. A WO layer 60 and an ITO layer 70 are provided between the first electrode 40 and the oxide semiconductor layer 10 and between the second electrode 50 and the oxide semiconductor layer 10.

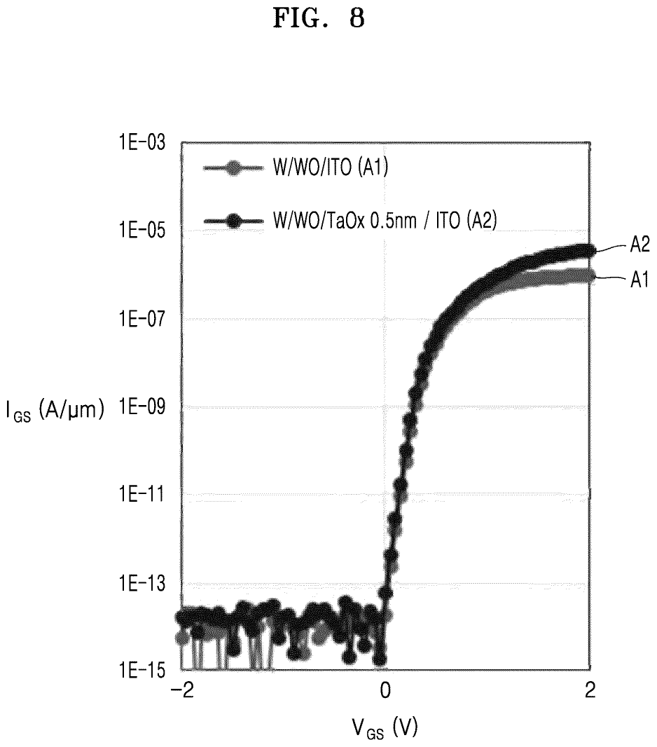

FIG. 8 is a current-voltage (I-V) graph for comparison between a semiconductor device of according to some example embodiments and a semiconductor device of a comparative example. The semiconductor device according to some example embodiments has a stacked structure of W electrode/WO/TaOₓ/ITO. Here, the TaOₓ has a thickness of 0.5 nm. Referring to FIG. 8, the semiconductor device according to some example embodiments (curve A2) has a higher on-current Iₒₙ than the semiconductor device of the comparative example (curve A1). The on-current Iₒₙ of the semiconductor device of example embodiments and the on-current Iₒₙ of the semiconductor device of the comparative example are as follows:

TABLE 1

| Items | Vt | Iₒₙ (nA/μm) |
|---|---|---|
| Comparative example | 0.1 | 551 |
| Embodiment | 0.1 | 987 |

Referring to FIG. 8 and Table 1, a contact resistance of the semiconductor devices 100, 200, and 300 of example embodiments may be reduced.

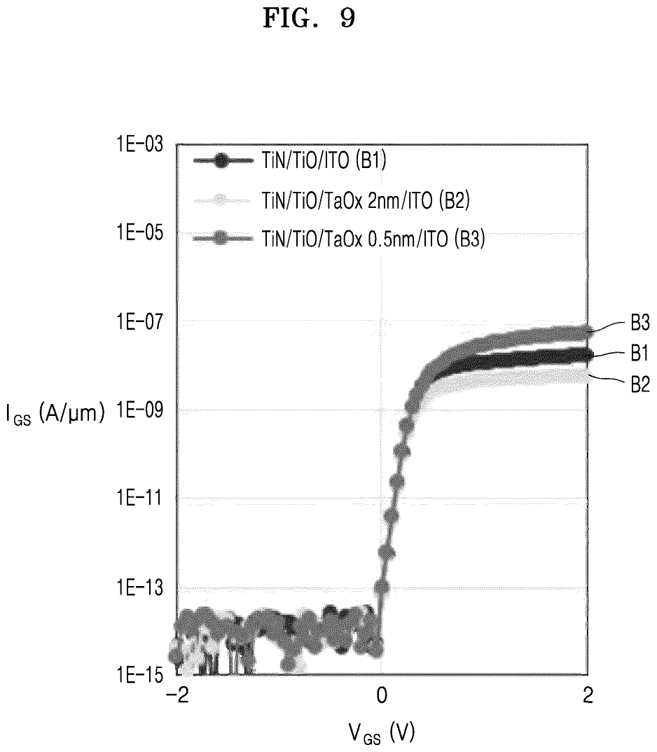

FIG. 9 is an I-V graph obtained by varying the thickness of a second layer. A curve B1 of a comparative example corresponds to a structure of TiN electrode/TiO₂ layer/ITO layer. A curve B2 corresponds to a structure of TiN electrode/TiO₂ layer (2 nm)/TaOₓ layer/ITO layer, and a curve B3 corresponds to a structure of TIN electrode/TiO² layer (0.5 nm)/TaOₓ layer/ITO layer.

On-current in each case is as follows:

TABLE 2

| Items | Vt | Iₒₙ (nA/μm) |
|---|---|---|
| B1 | 0.1 | 12 |
| B2 | 0.1 | 5 |
| B3 | 0.1 | 32 |

Referring to FIG. 9 and Table 2, when a TaOₓ layer has a thickness of 2 nm (curve B2), the on-current is lower than that in a comparative example (curve B1). The thickness of each of the second layers 130 and 330 of the semiconductor devices 100, 200, and 300 of example embodiments described above may be in a range of greater than about 0 to less than about 2 nm. The second layers 130 and 330 including TaOₓ may reduce contact resistance by lowering an energy barrier height between an electrode and an oxide semiconductor layer. However, the second layers 130 and 330 have low conductivity, and thus, when the second layers 130 and 330 have a large thickness, an energy barrier width may increase, resulting in an increase on-current. Therefore, the second layers 130 and 330 may have a reduced or minimum thickness exhibiting an energy-barrier-height reducing effect.

Oxide semiconductors have a greater bandgap than silicon and may thus be applied to dynamic random access memory (DRAM) cell transistor channels requiring or using relatively low off-current. However, oxide semiconductor channels have greater contact resistance than silicon channels, resulting in relatively low on-current while reducing off-current. The semiconductor devices 100, 200, and 300 of some example embodiments overcome or help to overcome these characteristics of oxide semiconductor channels by reducing contact resistance and increasing on-current through the first layers 125 and 325, the second layers 130 and 330, and the third layers 135 and 335.

The third layers 135 and 335 may provide indium to the first layers 125 and 325, enabling the first layers 125 and 325 to be doped with indium. This mechanism may reduce an energy barrier height between an electrode and an oxide semiconductor channel. Although the third layers 136 and 335 have a high work function and may thus increase contact resistance, the second layers 130 and 330 may offset the increase or further reduce the contact resistance. Therefore, the semiconductor devices 100, 200, and 300 of some example embodiments may reduce contact resistance and increase on-current, and thus, various electronic apparatuses may employ the semiconductor devices 100, 200, and 300 of the embodiments.

Recently, silicon-based memory or logic devices have reached or are approaching limits of high integration, requiring or using channel lengths of several nanometers or several tens of nanometers. As a result, reducing off-current has become crucial. Alternatively or additionally, improvements are needed in characteristics such as subthreshold swing (SS) and on/off ratio, which are required or are used for clear distinction between an on-state and an off-state. Oxide semiconductor devices used in large-area display drivers are highly satisfactory in such characteristics (low off-current, low SS, and high on/off ratio). Therefore, oxide semiconductor devices having these characteristics have recently been applied to memory or logic devices. Alternatively or additionally, because oxide semiconductor devices allow for low-temperature processes (500° C. or lower), integration density may be increased by stacking oxide semiconductor devices on silicon-based devices.

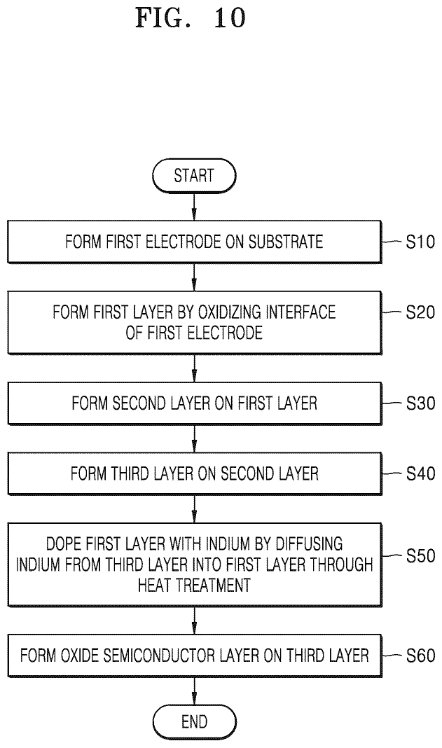

FIG. 10 is a flowchart illustrating a method of manufacturing a semiconductor device, according to some example embodiments. Operations of the manufacturing method are not limited to the order in which the operations are described below.

Referring to FIG. 10, a first electrode is formed on a substrate (S10). A first layer is formed by oxidizing, e.g., by thermally oxidizing, an interface of the first electrode (S20). The first layer may include a metal included in a first electrode. A second layer is formed on the first layer (S30). The second layer may include at least one selected from tantalum oxide, niobium oxide, strontium oxide, and aluminum oxide. A third layer is formed on the second layer (S40). The third layer may include indium oxide and/or ITO. The first, second, and third layers may be formed by one or more of a physical vapor deposition method, a chemical vapor deposition method, or an atomic layer deposition (ALD) method. The first layer is doped with indium by diffusing indium from the third layer to the first layer through a heat treatment process, such as but not limited to an annealing process (S50). As a result, the first layer may be converted into an indium-doped metal oxide layer. Doping with indium is not limited thereto. For example, doping with indium may be performed before and/or after forming an oxide semiconductor layer. An oxide semiconductor layer is formed on the third layer (S60). The deposition of the oxide semiconductor layer may involve an ALD process and/or a plasma-enhanced ALD (PE-ALD) process.

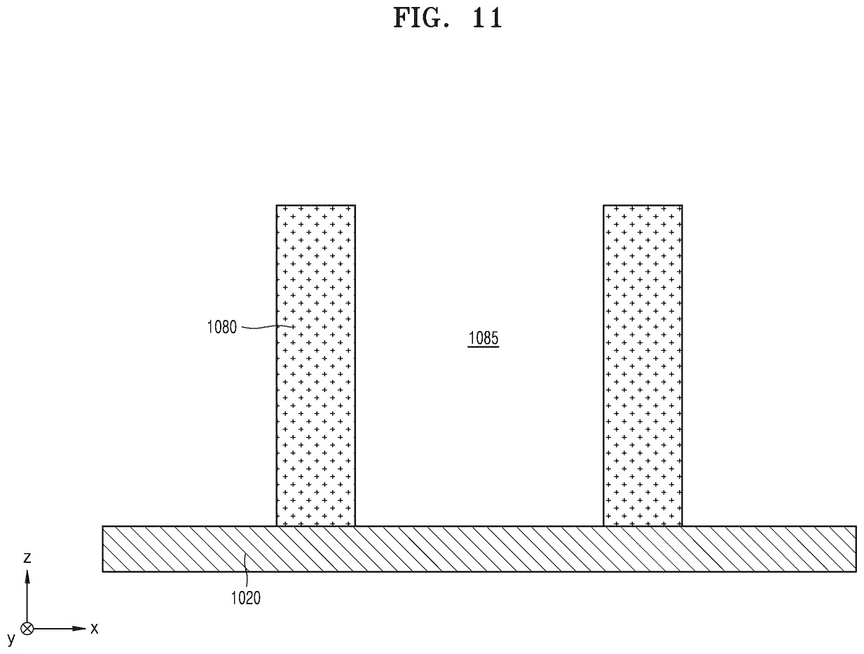

Next, a method of manufacturing a semiconductor device is described according to some example embodiments with reference to FIGS. 11 to 22.

Referring to FIG. 11, a plurality of mold insulating layers 1080 extending in a second horizontal direction y may be deposited on a first electrode 1020 extending in a first horizontal direction x. The mold insulating layers 1080 may be deposited to a height, such as to a predetermined height in a vertical direction z. The mold insulating layers 1080 and the first electrode 1020 may form an opening 1085.

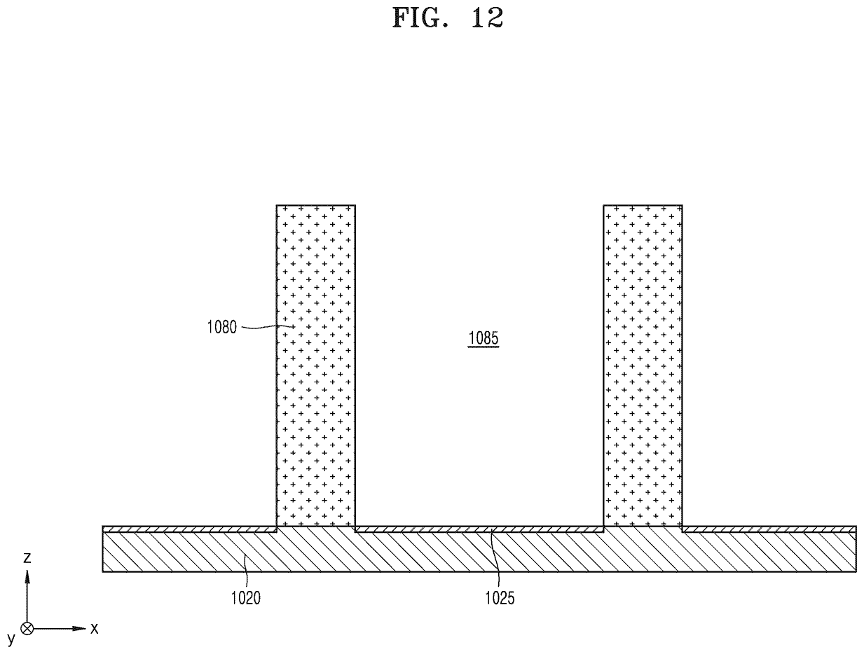

Referring to FIG. 12, a first layer 1025 may be deposited and/or grown and/or oxidized on the first electrode 1020. The first layer 1025 may include an oxide containing a metal included in the first electrode 1020. The first layer 1025 may be deposited, for example, using an ALD process and/or a thermal oxidation process. However, example embodiments are not limited thereto.

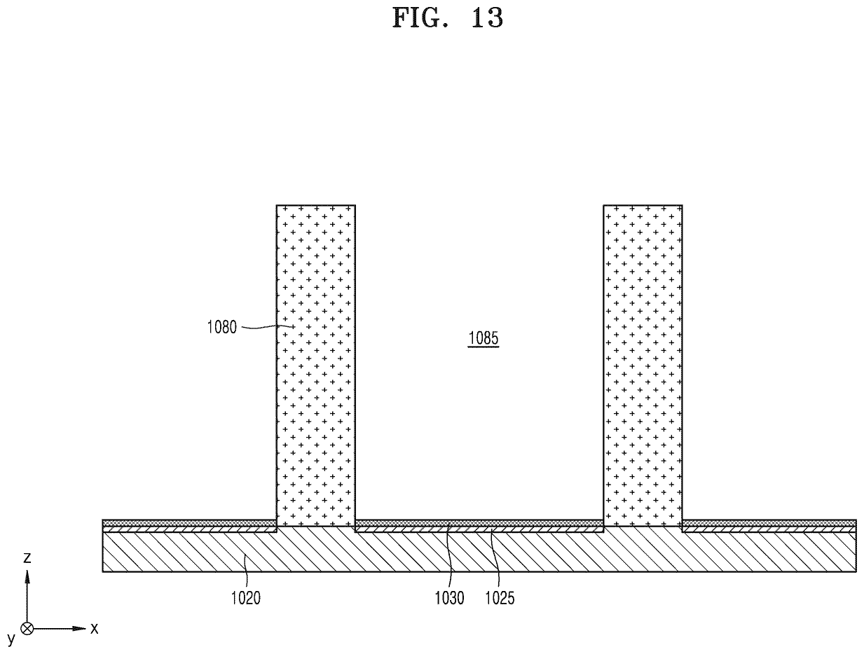

Referring to FIG. 13, a second layer 1030 may be deposited on the first layer 1025. The second layer 1030 may include at least one selected from tantalum oxide, niobium oxide, strontium oxide, and aluminum oxide. The second layer 1030 may be deposited, for example, using an ALD process.

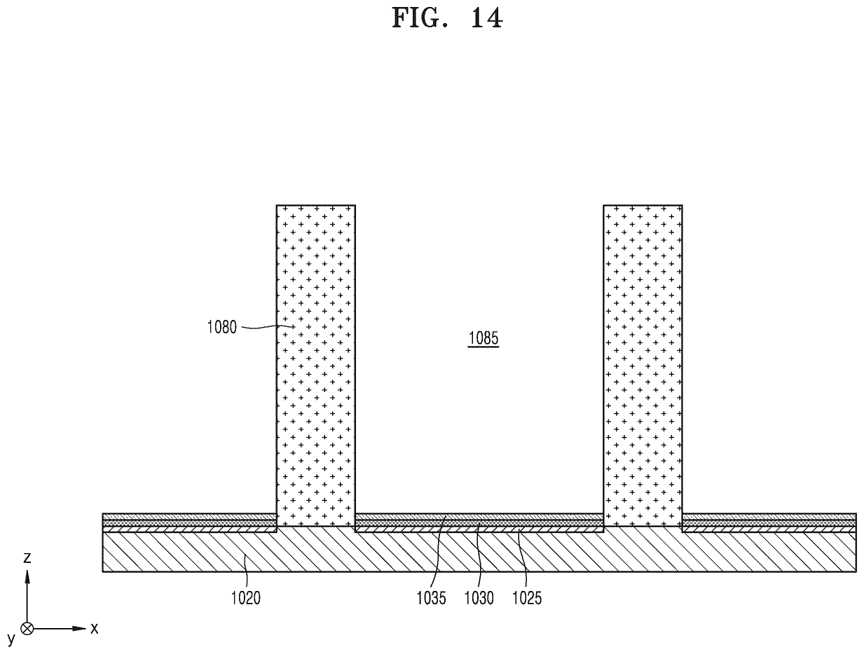

Referring to FIG. 14, a third layer 1035 may be formed on the second layer 1030. The third layer 1035 may include indium oxide or ITO. The third layer 1035 may be deposited, for example, using an ALD process. Thereafter, a heat treatment process, such as but not limited to an annealing process, may be performed to diffuse indium from the third layer 1035 into the first layer 1025, and thus, the first layer 1025 may include a metal oxide doped with indium.

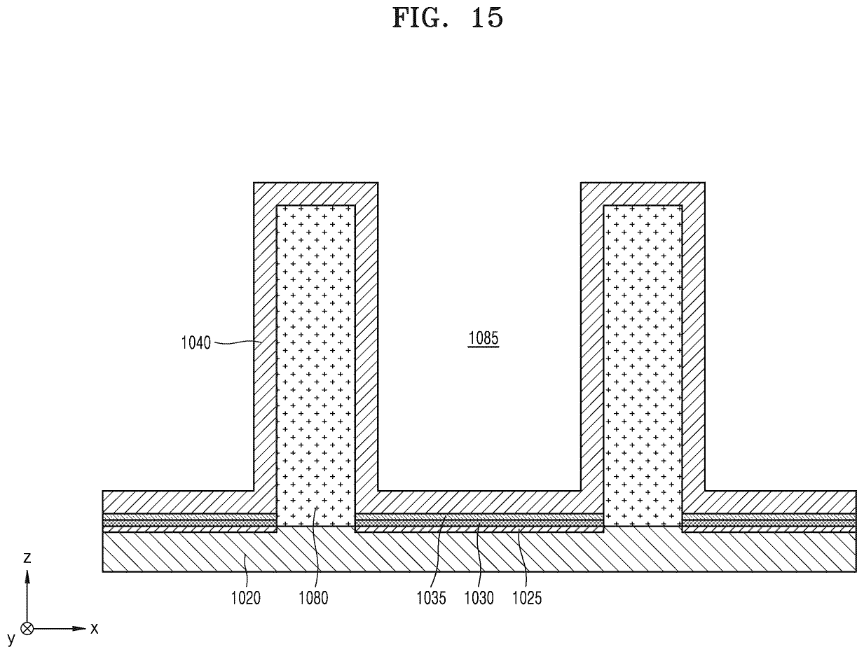

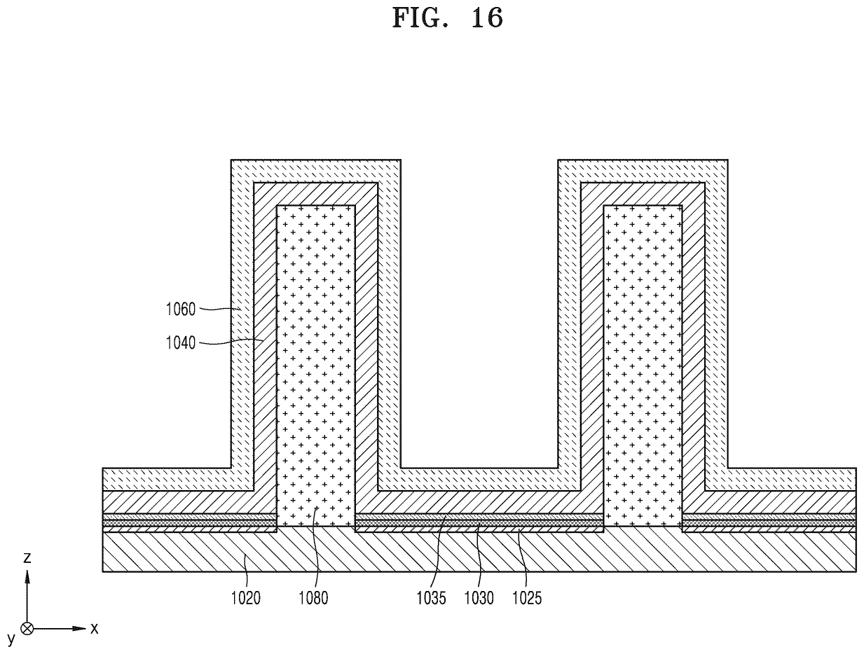

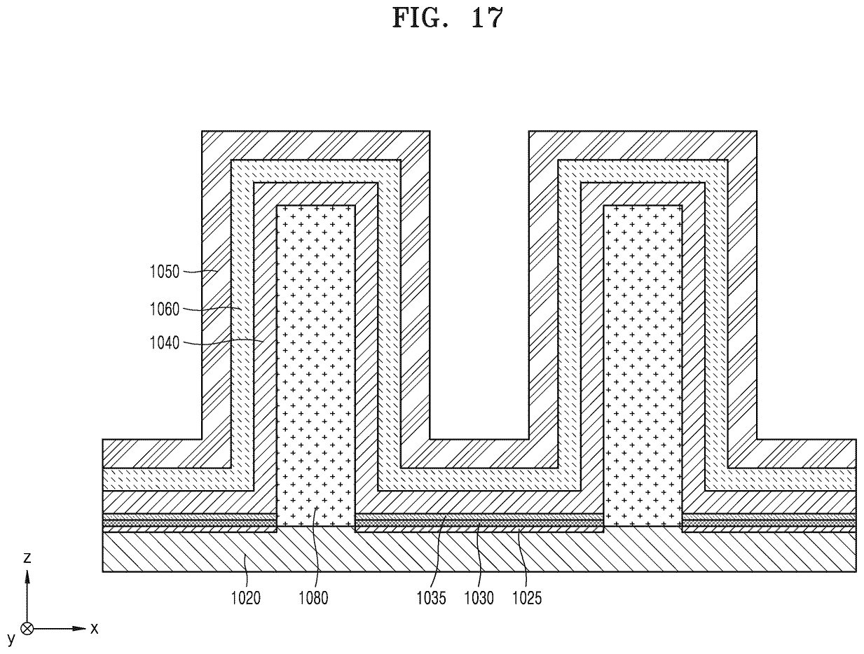

Referring to FIG. 15, an oxide semiconductor layer 1040 may be deposited on the third layer 1035 and the mold insulating layers 1080. The oxide semiconductor layer 1040 may be deposited using an ALD method. The oxide semiconductor layer 1040 may have a U-shaped cross-section. Referring to FIG. 16, a gate insulating layer 1060 may be deposited on the oxide semiconductor layer 1040. Referring to FIG. 17, a gate electrode 1050 may be deposited on the gate insulating layer 1060.

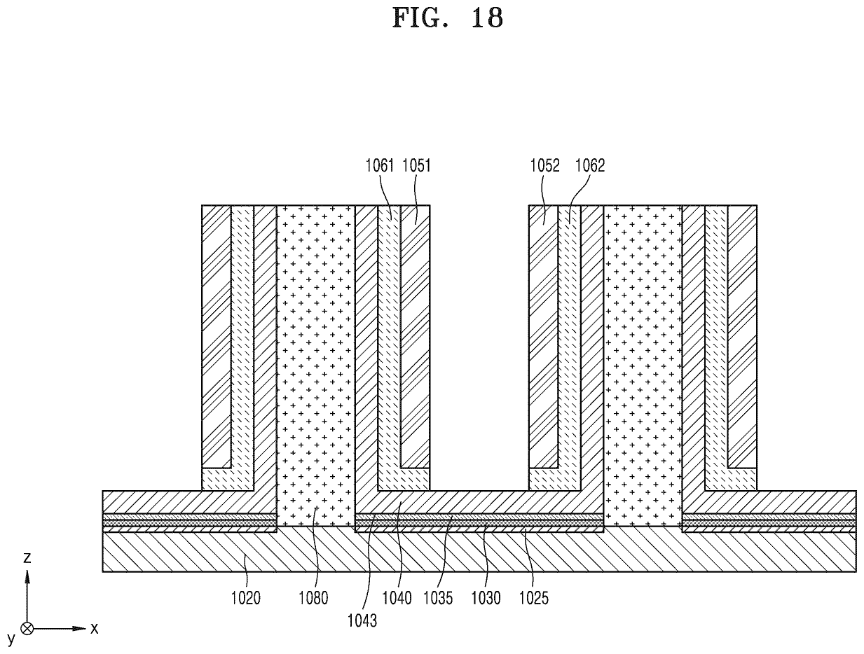

Referring to FIG. 18, anisotropic etching, such as a dry etching, may be performed on the gate electrode 1050 of a structure shown in FIG. 17, exposing a bottom portion 1043 of the oxide semiconductor layer 1040. As a result, the gate electrode 1050 may be separated into a first gate electrode 1051 and a second gate electrode 1052, and the gate insulating layer 1060 may be separated into a first gate insulating layer 1061 and a second gate insulating layer 1062. Alternatively or additionally, the gate electrode 1050, the gate insulating layer 1060, and the oxide semiconductor layer 1040 may be etched from upper sides of the mold insulating layers 1080, exposing upper surfaces of the mold insulating layers 1080. Upper surfaces of the mold insulating layer 1080, the first gate electrode 1051, the second gate electrode 1052, the first gate insulating layer 1061, and the second gate insulating layer 1062 may be at the same level.

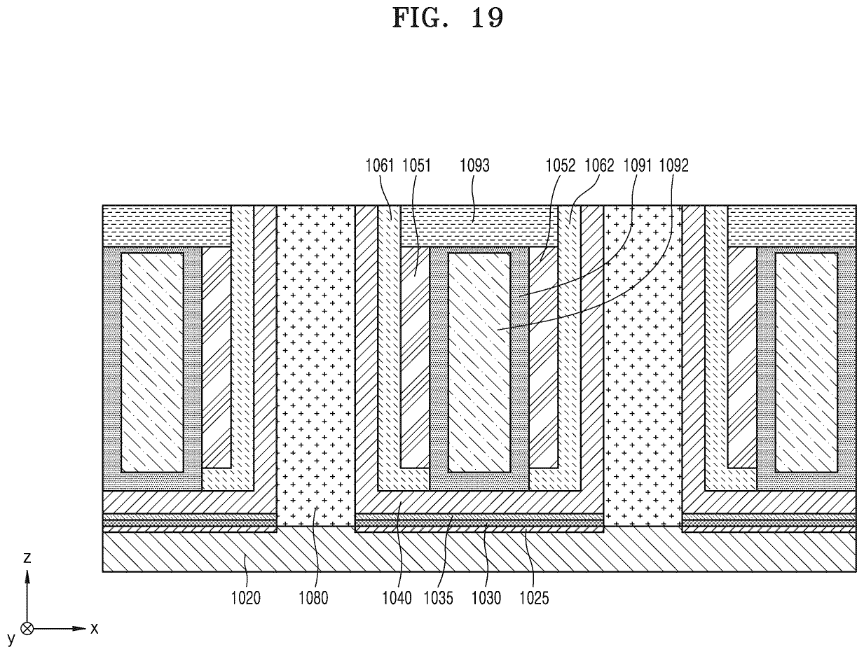

Referring to FIG. 19, the gate electrode 1050 may be etched one more time, and in this case, the upper surfaces of the first gate electrode 1051 and the second gate electrode 1052 may be lower than the upper surface level of the mold insulating layers 1080. An insulating liner 1091 may be deposited from a surface of the bottom portion 1043 of the oxide semiconductor layer 1040 up to the level of the upper surface of the first gate electrode 1051 and/or the level of the second gate electrode 1052. A filling insulating layer 1092 may fill the inside of the insulating liner 1091. The insulating liner 1091 and the filling insulating layer 1092 may not be distinct from each other. An upper insulating layer 1093 may be deposited on the upper surface of the first gate electrode 1051 and/or the upper surface of the second gate electrode 1052, and on an upper surface of the insulating liner 1091. A surface of the upper insulating layer 1093 may be at the same level as the upper surfaces of the mold insulating layers 1080, an upper surface of the oxide semiconductor layer 1040, the upper surface of the first gate electrode 1051, the upper surface of the second gate electrode 1052, the upper surface of the first gate insulating layer 1061, and the upper surface of the second gate insulating layer 1062.

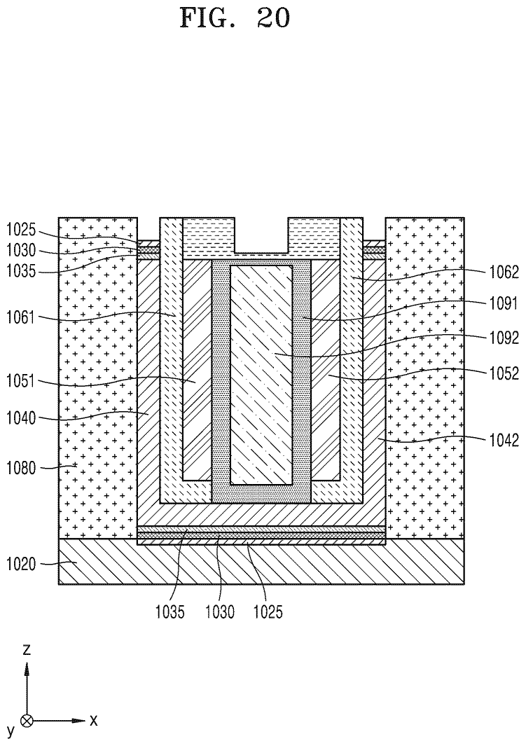

For ease of illustration, FIG. 20 illustrates only a portion of FIG. 19 that corresponds a pixel. Referring to FIG. 20, upper portions of the oxide semiconductor layer 1040 may be etched. Then, a third layer 1035, a second layer 1030, and a first layer 1025 may be sequentially deposited on the upper portions of the oxide semiconductor layer 1040.

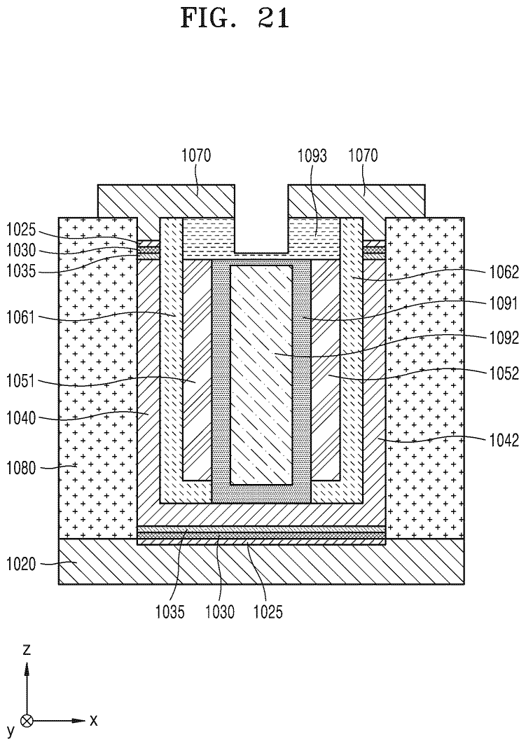

Referring to FIG. 21, second electrodes 1070 may be deposited on the first layer 1025. Thereafter, a heat treatment process such as but not limited to an annealing process may be performed to diffuse indium from the third layer 1035 into the first layer 1025, and thus, the first layer 1025 may include a metal oxide doped with indium. After depositing the second electrodes 1070, center portions of the second electrodes 1070 and an upper portion of the upper insulating layer 1093 may be partially etched.

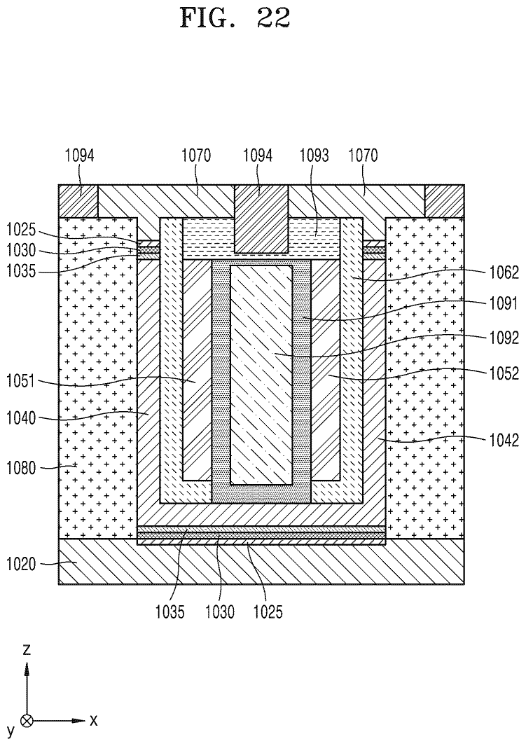

Referring to FIG. 22, a second electrode insulating layer 1094 may be deposited between the second electrodes 1070 and on the upper portion of the upper insulating layer 1093. An upper surface of the second electrode insulating layer 1094 and surfaces of the second electrodes 1070 may be at the same level.

In the method of manufacturing a semiconductor device, according to some example embodiments, three layers may be formed between an electrode and an oxide semiconductor layer to reduce contact resistance at an interface between the electrode and the oxide semiconductor layer.

The semiconductor devices of the embodiments may have a small size and high electrical performance and may thus be applied to highly integrated circuit (IC) devices.

The semiconductor devices of the embodiments may form transistors of digital or analog circuits. In some example embodiments, the semiconductor devices may be used as high-voltage or low-voltage transistors. For example, the semiconductor devices of the embodiments may form high-voltage transistors in peripheral circuits of high-voltage nonvolatile memory devices, such as flash memory devices and/or electrically erasable and programmable read-only memory (EEPROM) devices. Alternatively or additionally, the semiconductor devices of some example embodiments may form transistors of IC chips used for or in one or more of liquid crystal displays (LCDs), light emitting device (LED) displays, or micro-LED displays. In addition, the semiconductor devices of the embodiments may be applied to DRAM.

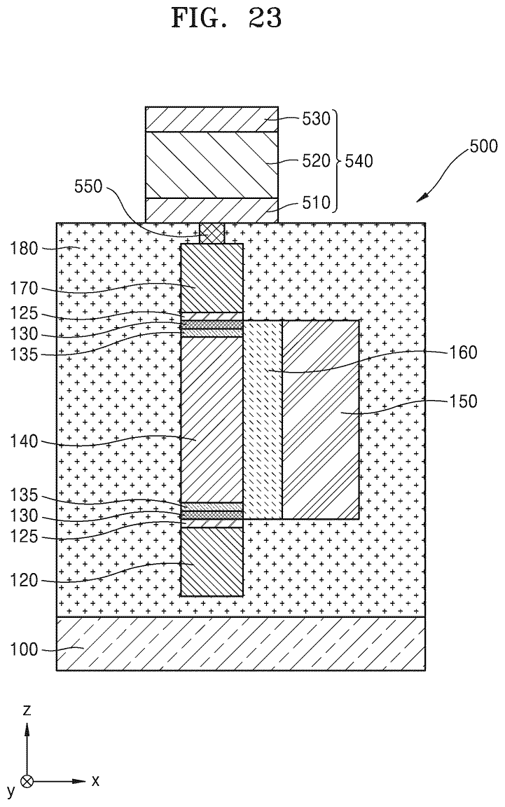

FIG. 23 is a view illustrating an electronic apparatus 500 in which a semiconductor device 100 is applied to DRAM according to some example embodiments.

The electronic apparatus 500 may include the semiconductor device 100 and a capacitor 540 electrically connected to the semiconductor device 100. For brevity, the description of the semiconductor device 100 may omit details that are substantially identical to those described with reference to reference to FIG. 1.

The capacitor 540 may include a third electrode 510, a dielectric layer 520, and a fourth electrode 530. The third electrode 510 and the fourth electrode 530 may have conductivity as electrodes, and may maintain stable capacitance performance even after high-temperature processes during the manufacturing of the capacitor 540. In one example, the third electrode 510 and the fourth electrode 530 independently or concurrently may include a metal, a metal nitride, a metal oxide, or a combination thereof. For instance, the third electrode 510 and the fourth electrode 530 may include TiN, NbN, MON, CON, TaN, W, Ru, RuO₂, SrRuO₃, Ir, IrO₂, Pt, PtO, SrRuO₃ (SRO), (Ba,Sr)RuO₃ (BSRO), CaRuO₃ (CRO), (La,Sr)CoO₃ (LSCO), or a combination thereof.

The dielectric layer 520 may include at least one selected from a dielectric material, a high-k material, and a ferroelectric material. The dielectric material may include, for example, silicon oxide. The high-k material refers to a material having a greater dielectric constant than silicon oxide. The high-k material may be a metal oxide including at least one selected from Ca, Sr, Ba, Sc, Y, La, Ti, Hf, Zr, Nb, Ta, Ce, Pr, Nd, Gd, Dy, Yb, and Lu. For example, the high-k material may include at least one selected from HfO₂, ZrO₂, CeO₂, La₂O₃, Ta₂O₃, and TiO₂. The ferroelectric material may include a ferroelectric having ferroelectricity, in which internal electric dipole moments align to maintain spontaneous polarization even in the absence of an externally applied electric field. When no external electric field is applied to the ferroelectric, the ferroelectric exhibit random polarization directions. However, when an external electric field is applied to the ferroelectric, the polarization magnitude of the ferroelectric increases for alignment with the direction of the external electric field. The ferroelectric retains the aligned polarization even after the external electric field is removed. The ferroelectric material may include at least one selected from a perovskite structure, a fluorite structure, and a wurtzite structure.

A contact 550 may be provided between a second electrode 170 and the third electrode 510. The contact 550 may electrically connect the second electrode 170 and the third electrode 510 to each other. The contact 550 may include a conductive material (for example, a metal).

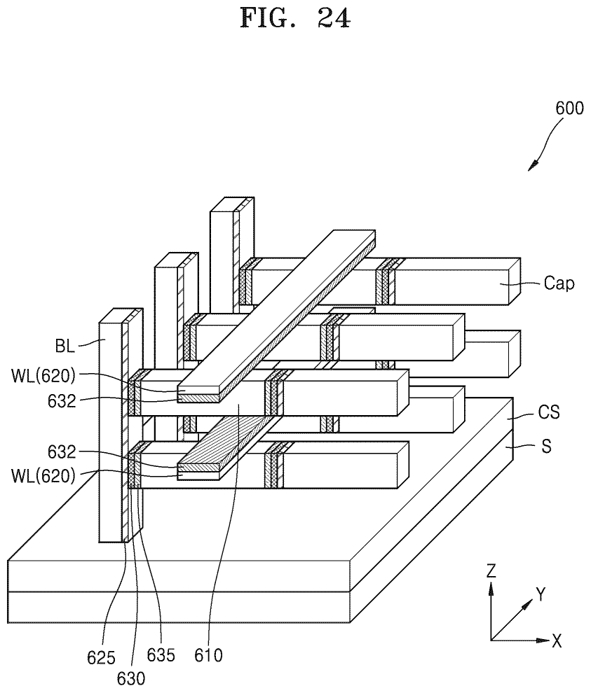

FIG. 24 is a schematic perspective view illustrating an example in which a semiconductor device is applied to a vertically stacked memory device 600 according to some example embodiments. Referring to FIG. 24, the vertically stacked memory device 600 may include a plurality of bit lines BL extending in a first direction (that is, a Z direction), a plurality of oxide semiconductor layers 610 connected to the bit lines BL and extending in a second direction (that is, an X direction) crossing, e.g., orthogonal to the first direction, a plurality capacitors Cap electrically and respectively connected to the oxide semiconductor layers 610, and a plurality word lines WL extending across the oxide semiconductor layers 610 in a third direction (that is, a Y direction) crossing, e.g., orthogonal to both the first and second directions. FIG. 24 illustrates that each of the word lines WL crosses over a corresponding oxide semiconductor layer 610 among the oxide semiconductor layers 610. However, embodiments are not limited thereto. For example, each of the word lines WL may cross under a corresponding oxide semiconductor layer 610.

The vertically stacked memory device 600 may further include a growth substrate S and a driving circuit substrate CS provided on the growth substrate S. The driving circuit substrate CS may include circuits connected to external circuits to receive data from the external circuits or output data to the external circuits. The circuits included in the driving circuit substrate CS may write data to the capacitors Cap or read data from the capacitors Cap.

The bit lines BL may be provided on the driving circuit substrate CS in a direction perpendicular to an upper surface of the driving circuit substrate CS. For ease of illustration, FIG. 24 shows only three bit lines BL that are arranged in a row at intervals in the third direction. In practice, however, a larger number of bit lines BL may be two-dimensionally arranged. For instance, a plurality bit lines BL extending in a vertical direction (that is, in the first direction) may be two-dimensionally arranged on the driving circuit substrate CS at regular intervals in the second and third directions. The bit lines BL may be parallel to each other.

A plurality of oxide semiconductor layers 610 connected to each of the bit lines BL may be arranged at intervals in the first direction. For ease of illustration, FIG. 24 shows only two oxide semiconductor layers 610 for each of the bit lines BL. However, a large number of oxide semiconductor layers 610 may be arranged at intervals in the first direction. Furthermore, in the same layer, a plurality oxide semiconductor layers 610 may be arranged at regular intervals in the third direction. The oxide semiconductor layers 610 arranged in the same layer may be connected to the bit lines BL, respectively. Like the bit lines BL, the oxide semiconductor layers 610 may be two-dimensionally arranged at regular intervals in the second and third directions. Each of the oxide semiconductor layers 610 may extend in the second direction. A first end of each of the oxide semiconductor layers 610 may be electrically connected to a corresponding bit line BL among the bit lines BL. The bit lines BL may correspond to a first electrode of the semiconductor device. A second end of each of the oxide semiconductor layers 610, opposite the first end in the second direction, may be electrically connected to a capacitor Cap.

A first layer 625, a second layer 630, and a third layer 635 may be disposed between each of the oxide semiconductor layers 610 and each of the bit lines BL. In addition, a first layer 625, a second layer 630, and a third layer 635 may be disposed between each of the oxide semiconductor layers 610 and each of the capacitors Cap. Although FIG. 24 illustrates that the first layers 625, the second layers 630, and the third layers 635 are disposed on both ends of each of the oxide semiconductor layers 610, embodiments are not limited thereto. For example, the first layer 625, the second layer 630, and the third layer 635 may be disposed on only one end of each of the oxide semiconductor layers 610.

For ease of illustration, FIG. 24 illustrates each of the capacitors Cap as a single block. In practice, however, each of the capacitors Cap may include a first electrode, a second electrode, and a dielectric layer between the first and second electrodes. The first electrode of each of the capacitors Cap may be electrically connected to the second end of a corresponding oxide semiconductor layer 610 among the oxide semiconductor layers 610. That is, the oxide semiconductor layers 610 and the capacitors Cap may be connected to each other in a one-to-one manner. Although not shown in FIG. 24, the second electrode of each of the capacitors Cap may be connected to a ground line of the vertically stacked memory device 600.

Each of the word lines WL may extend in the third direction while crossing over a corresponding oxide semiconductor layer 610 among the oxide semiconductor layers 610. In addition, the word lines WL may be arranged at intervals in the first direction. For ease of illustration, FIG. 24 illustrates one word line WL in one layer. However, in one layer, a plurality word lines WL may be arranged parallel to each other at intervals in the second direction.

A gate insulating layer 632 may be disposed between each of the oxide semiconductor layers 610 and each of the word lines WL. Although not illustrated in FIG. 24 for ease of illustration, the vertically stacked memory device 600 may further include an insulating material filled between the bit lines BL, the oxide semiconductor layers 610, and the word lines WL.

Each of the oxide semiconductor layers 610 may form an oxide semiconductor transistor together with a corresponding word line WL, a corresponding bit line BL, and the first electrode of a corresponding capacitor Cap. A first electrode of the oxide semiconductor transistor may be an element of the corresponding bit line BL, a gate electrode of the oxide semiconductor transistor may be an element of the corresponding word line WL, and a second electrode of the oxide semiconductor transistor may either serve as the first electrode of the corresponding capacitor Cap or be configured as a separate electrode. However, embodiments are not limited thereto. The first electrode, the gate electrode, and the second electrode may be provided as separate layers and electrically connected to the corresponding bit line BL, the corresponding word line WL, and the first electrode of the corresponding capacitor Cap.

The corresponding word line WL may serve as the gate electrode of the oxide semiconductor transistor as described above, and when a gate signal exceeding a threshold voltage is applied to the corresponding word line WL, current may flow through the oxide semiconductor layer 610. Then, the corresponding bit line BL and the corresponding capacitor Cap may be electrically connected to each other, and thus, data may be written to the corresponding capacitor Cap or read from the corresponding capacitor Cap.

Thus, one oxide semiconductor layer 610 and a corresponding capacitor Cap may form one memory cell, e.g., form a one oxide transistor, one capacitor (1OT1C) memory cell. The vertically stacked memory device 600 of the embodiment may include a plurality of two-dimensionally arranged memory cells in each layer. In addition, the vertically stacked memory device 600 may have a structure in which a plurality layers, each containing a plurality of two-dimensionally arranged memory cells, are stacked. As a result, the vertically stacked memory device 600 may have high integration density and thus high storage capacity.

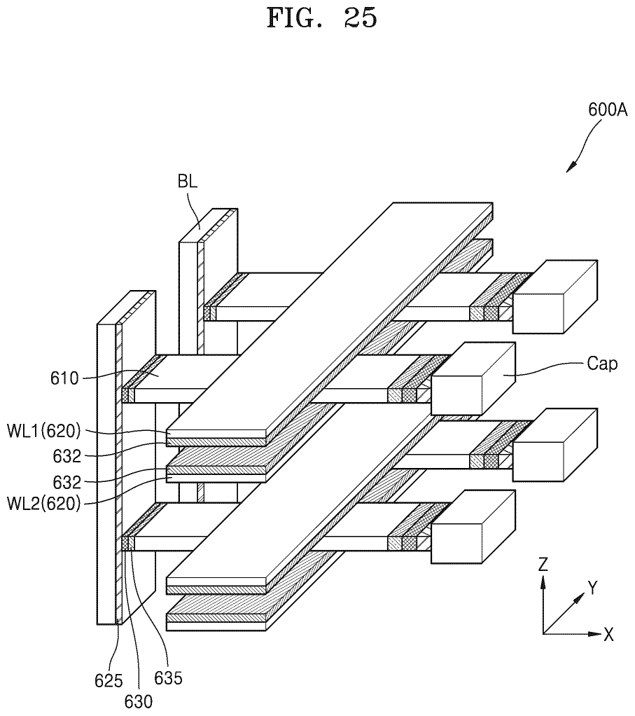

FIG. 25 is a perspective schematically illustrating a configuration of a vertically stacked memory device 600A according to some example embodiments. Referring to FIGS. 24 and 25, the vertically stacked memory device 600A shown in FIG. 25 may have a dual-gate structure. For example, the vertically stacked memory device 600A may include first word lines WL1 each extending in a third direction while crossing over a plurality oxide semiconductor layers 610 arranged on the same layer, and second word lines WL2 each extending in the third direction while crossing under a plurality oxide semiconductor layers 610 arranged on the same layer. The first word lines WL1 and the second word lines WL2 may be apart from each other in a first direction with corresponding oxide semiconductor layers 610 therebetween while facing each other in parallel. For example, referring to FIG. 25, each of the word lines WL may include a first word line WL1 and a second word line WL2 arranged apart from each other in the first direction with a corresponding oxide semiconductor layer 610 therebetween while facing each other in parallel.

Each of the oxide semiconductor layers 610 may form an oxide semiconductor transistor together with a corresponding first word line WL1 and a corresponding second word line WL2. Operations of the oxide semiconductor transistor may be controlled jointly by the first word line WL1 positioned above the oxide semiconductor layer 610 and the second word line WL2 positioned below the oxide semiconductor layer 610. As a result, the driving reliability of the oxide semiconductor transistor may be improved. The other elements of the vertically stacked memory device 600A shown in FIG. 25 may be substantially the same as the elements of the vertically stacked memory device 600 shown in FIG. 24, and thus, repeated descriptions thereof are omitted here.

FIGS. 24 and 25 illustrate that the bit lines BL are vertically to the upper surface of the driving circuit substrate CS, and the word lines WL are parallel to the upper surface of the driving circuit substrate CS. However, embodiments are not limited thereto. For example, the bit lines BL may be parallel to the upper surface of the driving circuit substrate CS, and the word lines WL may be vertical to the upper surface of the driving circuit substrate CS. That is, the oxide semiconductor layers 610 and the capacitors Cap may be sequentially arranged starting from the driving circuit substrate CS.

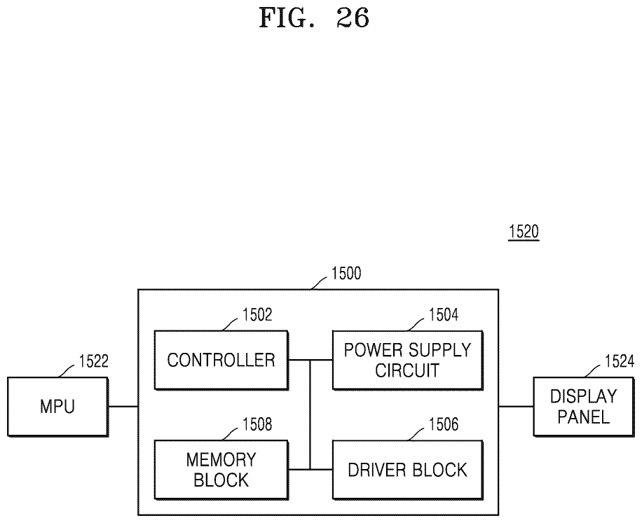

FIG. 26 is a block diagram schematically illustrating a display apparatus 1520 including a display driver IC (DDI) 1500 according to some example embodiments.

Referring to FIG. 26, the DDI 1500 may include a controller 1502, a power supply circuit 1504, a driver block 1506, and a memory block 1508. The controller 1502 receives and decodes instructions from a main processing unit (MPU) 1522 and controls each block of the DDI 1500 to perform operations according to the instructions. The power supply circuit 1504 generates driving voltages in response to control by the controller 1502. The driver block 1506 drives a display panel 1524 using the driving voltages generated by the power supply circuit 1504 in response to control by the controller 1502. The display panel 1524 may include an LCD panel or a micro-LED device. The memory block 1508 may temporarily store instructions input to the controller 1502, control signals output from the controller 1502, or other necessary data. The memory block 1508 may include memory such as random-access memory (RAM) or read-only memory (ROM). The power supply circuit 1504 and the driver block 1506 may include the semiconductor devices of the embodiments described above.

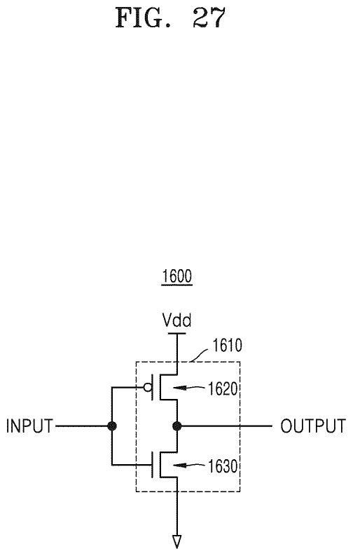

FIG. 27 is a circuit diagram illustrating a complementary metal oxide semiconductor (CMOS) inverter 1600 according to some example embodiments.

The CMOS inverter 1600 includes a CMOS transistor 1610. The CMOS transistor 1610 includes a p-channel metal-oxide semiconductor (PMOS) transistor 1620 and an n-channel metal-oxide semiconductor (NMOS) transistor 1630 that are connected between a power supply terminal Vdd and a ground terminal. The CMOS transistor 1610 may include the semiconductor device of any one or more of example embodiments described above.

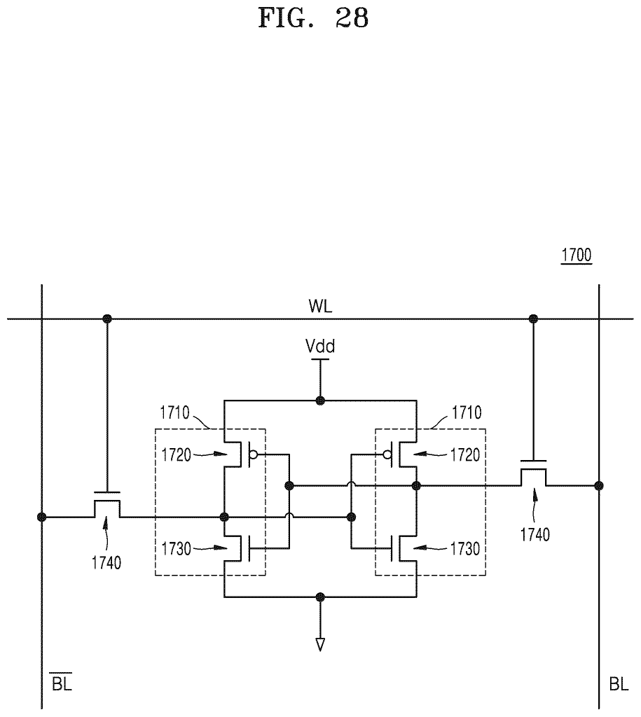

FIG. 28 is a circuit diagram illustrating a CMOS static random access memory (SRAM) device 1700 according to some example embodiments.

The CMOS SRAM device 1700 includes a pair of driving transistors 1710. Each of the pair of driving transistors 1710 includes a PMOS transistor 1720 and an NMOS transistor 1730 that are connected between a power supply terminal Vdd and a ground terminal. The CMOS SRAM device 1700 may further include a pair of transfer transistors 1740. A source of each of the pair of transfer transistors 1740 is cross-connected to a common node of the PMOS transistor 1720 and the NMOS transistor 1730 of each of the pair of driving transistors 1710. A source of the PMOS transistor 1720 is connected to the power supply terminal Vdd, and a source of the NMOS transistor 1730 is connected to the ground terminal. Gates of the pair of transfer transistors 1740 may be connected to a word line WL, and drains of the pair of transfer transistors 1740 may be respectively connected to a bit line BL and an inverted bit line.

At least one of the pair of driving transistors 1710 and the pair of transfer transistors 1740 of the CMOS SRAM device 1700 may include the semiconductor device of any one of the embodiments described above.

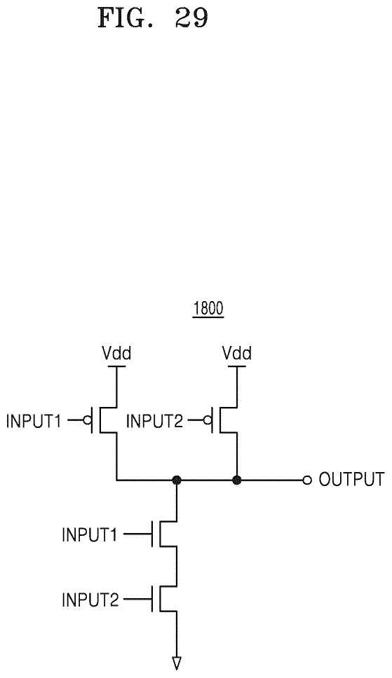

FIG. 29 is a circuit diagram of a CMOS NAND circuit 1800 according to some example embodiments.

The CMOS NAND circuit 1800 includes a pair of CMOS transistors receiving different input signals. The CMOS NAND circuit 1800 may include the semiconductor device of any one of the embodiments described above.

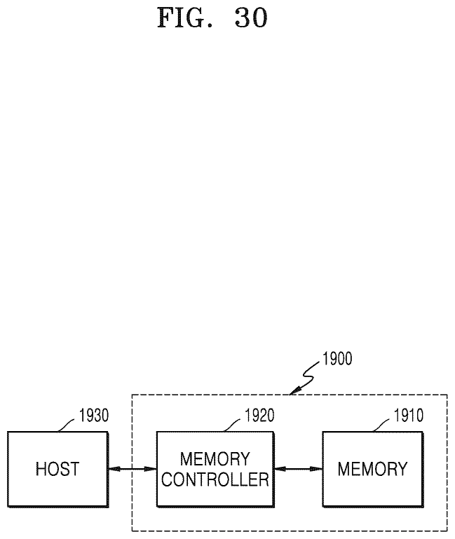

FIG. 30 is a block diagram illustrating an electronic system 1900 according to some example embodiments.

The electronic system 1900 includes memory 1910 and a memory controller 1920. The memory controller 1920 controls the memory 1910 to read data from or write data to the memory 1910 in response to requests from a host 1930. At least one of the memory 1910 and the memory controller 1920 may include the semiconductor device of any one of the embodiments described above.

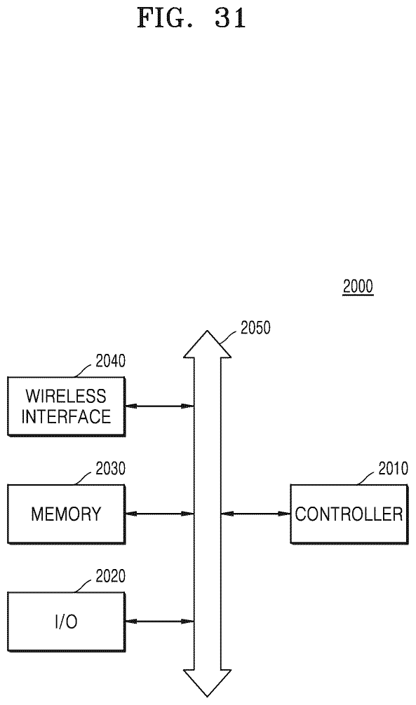

FIG. 31 is a block diagram illustrating an electronic system 2000 according to some example embodiments.

The electronic system 2000 may form a wireless communication device or a device capable of transmitting and/or receiving information in a wireless environment. The electronic system 2000 includes a controller 2010, an input/output (I/O) device 2020, memory 2030, and a wireless interface 2040 that are connected to each other via a bus 2050.

The controller 2010 may include at least one selected from a microprocessor, a digital signal processor, and a similar processing device. The I/O device 2020 may include at least one selected from a keypad, keyboard, and a display. The memory 2030 may store instructions executed by the controller 2010. For example, the memory 2030 may store user data. The electronic system 2000 may use the wireless interface 2040 to transmit/receive data over a wireless communication network. The wireless interface 2040 may include an antenna and/or a wireless transceiver. The electronic system 2000 may include the semiconductor device of any one of the embodiments described above.

The semiconductor devices of the embodiments described above have a small size and high electrical performance and may thus be to integrated circuit devices for one or more of miniaturization, low power consumption, and high performance.

As described above, according to one or more example embodiments described above, the semiconductor device includes three layers between an electrode and an oxide semiconductor layer, thereby decreasing contact resistance and increasing on-current. According to one or more example embodiments described above, the method of manufacturing a semiconductor device enables the formation of three layers between an electrode and an oxide semiconductor layer for reducing contact resistance between the electrode and the oxide semiconductor layer.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

It should be understood that example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a substrate;
an oxide semiconductor layer on the substrate;
a first electrode on the oxide semiconductor layer;
a second electrode on the oxide semiconductor layer and located apart from the first electrode;
a first layer, a second layer, and a third layer in at least one of a region between the oxide semiconductor layer and the first electrode and a region between the oxide semiconductor layer and the second electrode;
a gate insulating layer on the oxide semiconductor layer; and
a gate electrode on the gate insulating layer,
wherein the first layer includes an indium-containing metal oxide layer comprising at least one of metals included in the first electrode or the second electrode,
the second layer comprises at least one selected from tantalum oxide, niobium oxide, strontium oxide, and aluminum oxide, and
the third layer comprises at least one of indium oxide or indium tin oxide.

2. The semiconductor device of claim 1, wherein the first electrode and the second electrode independently comprise at least one selected from W, TIN, Mo, MoN, Ru, and TiSiN.

3. The semiconductor device of claim 1, wherein the first layer comprises at least one selected from indium-containing TiO₂, indium-containing WOₓ, indium-containing MoOₓ, and indium-containing RuO.

4. The semiconductor device of claim 1, wherein the second layer has a thickness greater than 0 nm to less than 2 nm.

5. The semiconductor device of claim 1, wherein the first electrode and the second electrode are apart from each other in a direction perpendicular to the substrate.

6. The semiconductor device of claim 1, wherein the oxide semiconductor layer comprises an oxide comprising at least one selected from indium (In), gallium (Ga), zinc (Zn), tungsten (W), tin (Sn), and hafnium (Hf).

7. The semiconductor device of claim 1, wherein the gate electrode surrounds the oxide semiconductor layer.

8. The semiconductor device of claim 1, wherein length directions of the oxide semiconductor layer, the gate insulating layer, and the gate electrode are perpendicular to the substrate, and the oxide semiconductor layer, the gate insulating layer, and the gate electrode are arranged in a direction parallel to the substrate.

9. The semiconductor device of claim 1, wherein the oxide semiconductor layer has a U-shaped cross-section.

10. The semiconductor device of claim 1, wherein
the oxide semiconductor layer comprises: a first oxide semiconductor layer having an L shape with a length in a direction perpendicular to the substrate, and a second oxide semiconductor layer symmetrical to the first oxide semiconductor layer with respect to the direction perpendicular to the substrate, and
the gate electrode comprises: a first gate electrode having a length in the direction perpendicular to the substrate, and a second gate electrode symmetrical to the first gate electrode with respect to the direction perpendicular to the substrate.

11. The semiconductor device of claim 1, wherein the first electrode, the first layer, the second layer, the third layer, and the oxide semiconductor layer have an identical width.

12. An electronic apparatus comprising:
a semiconductor device;
a capacitor electrically connected to the semiconductor device,
wherein the semiconductor device comprises:
a substrate;
an oxide semiconductor layer on the substrate;
a first electrode on the oxide semiconductor layer;
a second electrode provided on the oxide semiconductor layer and located apart from the first electrode;
a first layer, a second layer, and a third layer that are provided in at least one of a region between the oxide semiconductor layer and the first electrode and a region between the oxide semiconductor layer and the second electrode;
a gate insulating layer provided on the oxide semiconductor layer; and
a gate electrode provided on the gate insulating layer,
wherein the first layer includes an indium-containing metal oxide layer comprising at least one of metals included in the first electrode or the second electrode,
the second layer comprises at least one selected from tantalum oxide, niobium oxide, strontium oxide, and aluminum oxide, and
the third layer comprises at least one of indium oxide or indium tin oxide.

13. The electronic apparatus of claim 12, wherein the first electrode and the second electrode independently comprise at least one selected from W, TiN, Mo, MoN, Ru, and TiSiN.

14. The electronic apparatus of claim 12, wherein the first layer comprises at least one selected from indium-containing TiO₂, indium-containing WOₓ, indium-containing MoOₓ, and indium-containing RuO.

15. The electronic apparatus of claim 12, wherein the second layer has a thickness greater than 0 nm to less than 2 nm.

16. The electronic apparatus of claim 12, wherein the first electrode and the second electrode are arranged apart from each other in a direction perpendicular to the substrate.

17. The electronic apparatus of claim 12, wherein
the first electrode comprises a plurality of bit lines extending in a first direction,
the oxide semiconductor layer comprises a plurality of oxide semiconductor layers respectively and electrically connected to the plurality of bit lines and extending in a second direction crossing the first direction, and
the gate electrode comprises a plurality of word lines extending across the plurality of oxide semiconductor layers in a third direction crossing the first and second directions.

18. A method of manufacturing a semiconductor device, the method comprising:
forming a first electrode on a substrate;
forming a first layer by oxidizing an interface of the first electrode;
forming a second layer on the first layer;
forming a third layer on the second layer;
doping the first layer with indium with a heat treatment diffusing indium from the third layer into the first layer; and
forming an oxide semiconductor layer on the third layer,
wherein the first layer includes an indium-containing metal oxide layer comprising at least one of metals included in the first electrode,
the second layer comprises at least one selected from tantalum oxide, niobium oxide, strontium oxide, and aluminum oxide, and
the third layer comprises at least one of indium oxide or indium tin oxide.

19. The method of claim 18, wherein the first layer comprises at least one selected from indium-containing TiO₂, indium-containing WOₓ, indium-containing MoOₓ, and indium-containing RuO.

20. The method of claim 18, wherein the second layer has a thickness greater than 0 to less than 2 nm.
